(19) United States
(12) Patent Application Publication
(10) Pub. No.: US 2026/0040559 A1
(43) Pub. Date: Feb. 5, 2026

(54) SEMICONDUCTOR STORAGE DEVICE AND METHOD OF MANUFACTURING SEMICONDUCTOR STORAGE DEVICE

(71) Applicant: Kioxia Corporation, Tokyo (JP)

(72) Inventors: Kohei HATTORI, Yokkaichi Mie (JP); Tatsuya ISHIKAWA, Yokkaichi Mie (JP); Takayuki KAKEGAWA, Yokkaichi Mie (JP); Yosuke MITSUNO, Yokkaichi Mie (JP); Yoichi MINEMURA, Yokkaichi Mie (JP); Ryo YOUGAUCHI, Yokkaichi Mie (JP)

(73) Assignee: Kioxia Corporation, Tokyo (JP)

(21) Appl. No.: 18/977,025

(22) Filed: Dec. 11, 2024

(30) Foreign Application Priority Data
Aug. 2, 2024 (JP) 2024-127884

(51) Int. Cl. H10B 43/35; H10B 43/20

(52) U.S. Cl. CPC H10B 43/35; H10B 43/20

(57) ABSTRACT

A semiconductor storage device according to one embodiment includes a multi-layered body and a columnar body. The multi-layered body includes a plurality of gate electrode layers and a plurality of insulating layers. When a direction intersecting a first direction is a second direction and a virtual centerline extending in the first direction through a center of the columnar body in the second direction is defined. The columnar body includes a memory film, a semiconductor film, and an insulating portion. The insulating portion includes a first insulating portion adjacent to a plurality of first selection gate lines, and a second insulating portion adjacent to at least a part of word lines. When a region between the centerline and the semiconductor film is viewed, a thickness of the second insulating portion in the second direction is smaller than a thickness of the first insulating portion in the second direction.

### CROSS-REFERENCE TO RELATED APPLICATION

This application is based upon and claims the benefit of priority from Japanese Patent Application No. 2024-127884, filed on Aug. 2, 2024, the entire contents of which are incorporated herein by reference.

### FIELD

An embodiment of the present invention relates to a semiconductor storage device and a method of manufacturing a semiconductor storage device.

### BACKGROUND ART

NAND-type flash memories including three-dimensionally disposed memory cells are known.

### BRIEF DESCRIPTION OF THE DRAWINGS

FIG. 1 is a block diagram showing a part of a semiconductor storage device of a first embodiment.

FIG. 2 is a view showing an equivalent circuit of a part of a memory cell array of the first embodiment.

FIG. 3 is a cross-sectional view showing a part of the semiconductor storage device of the first embodiment.

FIG. 4 is a cross-sectional view showing the semiconductor storage device shown in FIG. 3 along line F4-F4.

FIG. 5 is an enlarged cross-sectional view showing a region surrounded by line F5 in the memory cell array shown in FIG. 3.

FIG. 6 is a cross-sectional view showing the memory cell array shown in FIG. 5 along line F6-F6.

FIG. 7 is an enlarged cross-sectional view showing a region surrounded by line F7 in the memory cell array shown in FIG. 5.

FIG. 8 is an enlarged cross-sectional view showing a region surrounded by line F8 in the memory cell array shown in FIG. 7.

FIG. 9 is a view showing a profile of an impurity concentration in an insulating portion of the first embodiment.

FIG. 10A is an explanatory cross-sectional view showing a method of manufacturing a semiconductor storage device of the first embodiment.

FIG. 10B is another explanatory cross-sectional view showing the method of manufacturing a semiconductor storage device of the first embodiment.

FIG. 10C is another explanatory cross-sectional view showing the method of manufacturing a semiconductor storage device of the first embodiment.

FIG. 10D is another explanatory cross-sectional view showing the method of manufacturing a semiconductor storage device of the first embodiment.

FIG. 10E is another explanatory cross-sectional view showing the method of manufacturing a semiconductor storage device of the first embodiment.

FIG. 10F is another explanatory cross-sectional view showing the method of manufacturing a semiconductor storage device of the first embodiment.

FIG. 10G is another explanatory cross-sectional view showing the method of manufacturing a semiconductor storage device of the first embodiment.

FIG. 10H is another explanatory cross-sectional view showing the method of manufacturing a semiconductor storage device of the first embodiment.

FIG. 10I is another explanatory cross-sectional view showing the method of manufacturing a semiconductor storage device of the first embodiment.

FIG. 10J is another explanatory cross-sectional view showing the method of manufacturing a semiconductor storage device of the first embodiment.

FIG. 10K is another explanatory cross-sectional view showing the method of manufacturing a semiconductor storage device of the first embodiment.

FIG. 11 is an explanatory view showing an influence of a thickness of a second insulating portion of the first embodiment.

FIG. 12 is a cross-sectional view showing the memory cell array of a first modification example of the first embodiment.

FIG. 13 is a cross-sectional view showing the memory cell array of a second modification example of the first embodiment.

FIG. 14 is an enlarged cross-sectional view showing a region surrounded by line F14 in the memory cell array shown in FIG. 13.

FIG. 15 is a cross-sectional view showing the memory cell array of a second embodiment.

FIG. 16 is a cross-sectional view showing the memory cell array of a third embodiment.

### DETAILED DESCRIPTION

A semiconductor storage device according to one embodiment includes a multi-layered body, a columnar body, and a bit line. The multi-layered body includes a plurality of gate electrode layers and a plurality of insulating layers. The plurality of gate electrode layers and the plurality of insulating layers are alternately stacked one by one in a first direction. The columnar body extends in the first direction inside the multi-layered body. The bit line is on a first side in the first direction with respect to the columnar body. The plurality of gate electrode layers include a plurality of word lines and a plurality of first selection gate lines. The plurality of word lines form first intersecting portions with the columnar body. The first intersecting portions has memory cell transistors. The plurality of first selection gate lines are on a second side opposite to the first side with respect to the plurality of word lines. The plurality of first selection gate lines form second intersecting portions with the columnar body. The second intersecting portions has first selection transistors. When a direction intersecting the first direction is a second direction and a virtual centerline extending in the first direction through a center of the columnar body in the second direction is defined in a cross section in the first direction and the second direction, it is as follows. The columnar body includes a memory film, a semiconductor film, an insulating portion, and a cavity portion. The memory film includes a charge accumulation portion. The semiconductor film is on an inner circumferential side of the memory film in the second direction. The insulating portion is on an inner circumferential side of the semiconductor film in the second direction. The cavity portion is adjacent to at least a part of the insulating portion in the first direction. The insulating portion includes a first insulating portion and a second insulating portion. The first insulating portion is adjacent to the plurality of first selection gate lines in the second direction. The second insulating portion is adjacent to the cavity portion in the second direction. The second insulating portion is adjacent to at least a part of word lines included in the plurality of word lines in the second direction. When a region between the centerline and the semiconductor film is viewed, a thickness of the second insulating portion in the second direction is smaller than a thickness of the first insulating portion in the second direction.

Hereinafter, a semiconductor storage device and a method of manufacturing a semiconductor storage device of an embodiment will be described with reference to the drawings. In the following description, the same signs will be applied to constituents having the same or similar functions. Furthermore, duplicate description of the constituents may be omitted. In the following description, when the reference signs with numerals and alphabetical characters at the end for distinguishment do not need to be distinguished from each other, the numerals and the alphabetical characters at the end may be omitted.

In this application, terms are defined as follows. “Parallel”, “orthogonal”, and “the same” may include cases of “substantially parallel”, “substantially orthogonal”, and “substantially the same”, respectively. “Connection” is not limited to mechanical connection and may include electrical connection. That is, “connection” is not limited to a case in which a plurality of elements are directly connected and may include a case in which a plurality of elements are connected with another element interposed therebetween. “Adjacent” is not limited to a case in which a plurality of elements are in contact with each other and may include a case in which a plurality of elements are adjacent to each other with another element interposed therebetween.

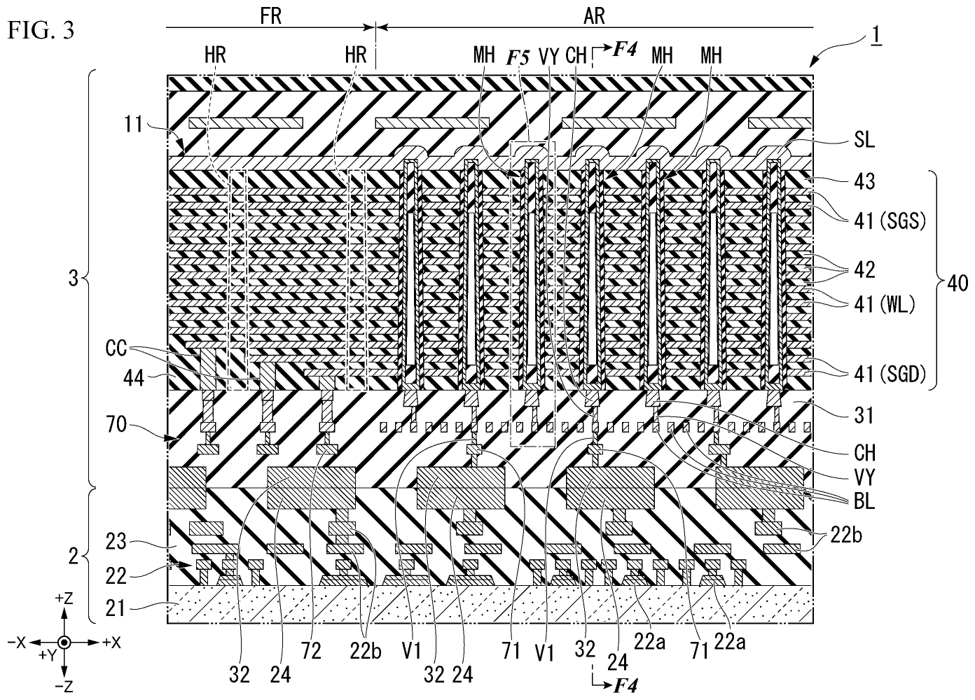

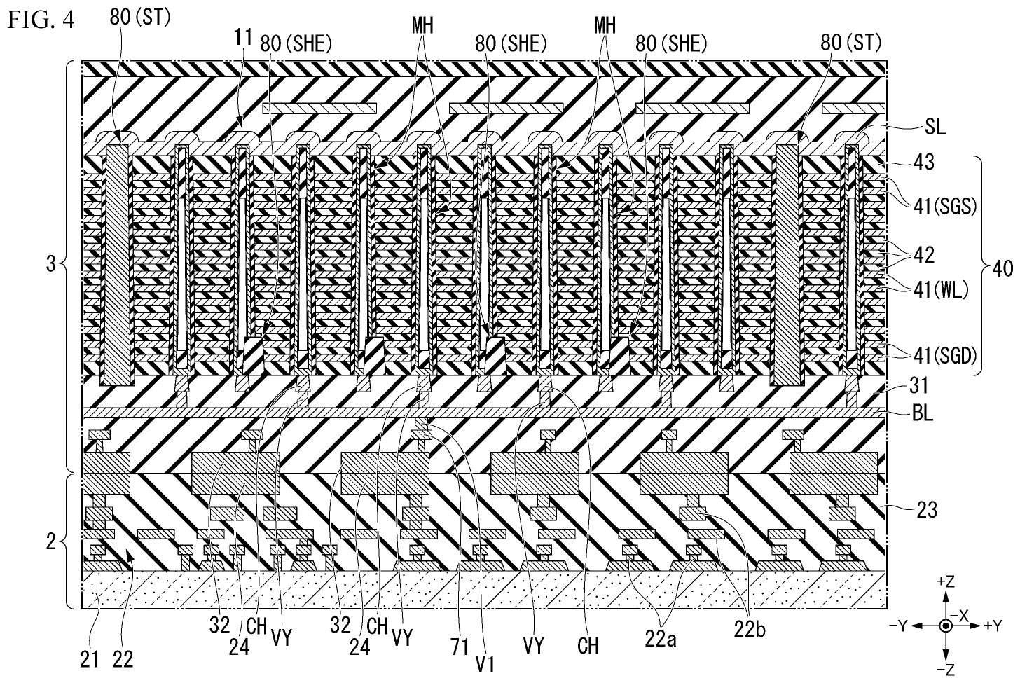

A +X direction, a −X direction, a +Y direction, a −Y direction, a +Z direction, and a −Z direction are defined as follows. The +X direction is a direction in which word lines WL (which will be described below) extend (refer to FIG. 3). The −X direction is a direction opposite to the +X direction. When there is no need to distinguish between the +X direction and the −X direction, it will be simply referred to as the X direction. The +Y direction is a direction intersecting (for example, orthogonal to) the X direction. The +Y direction is a direction in which bit lines BL extend (refer to FIG. 4). The −Y direction is a direction opposite to the +Y direction. When there is no need to distinguish between the +Y direction and the −Y direction, it will be simply referred to as the Y direction. The +Z direction is a direction intersecting (for example, orthogonal to) the X direction and the Y direction. The +Z direction is a direction toward a multi-layered body 40 from the bit lines BL (which will be described below) (refer to FIG. 3). The −Z direction is a direction opposite to the +Z direction. When there is no need to distinguish between the +Z direction and the −Z direction, it will be simply referred to as the Z direction. In this application, a side in the +Z direction may be referred to as “upward”, and a side in the −Z direction may be referred to as “downward”. In addition, in this application, a position in the Z direction may be referred to as “a height”. However, these expressions are used for the sake of convenience of description and do not stipulate the direction of gravity. The Z direction is an example of “a first direction”. The X direction is an example of “a second direction”. The side in the −Z direction is an example of “a first side”. The side in the +Z direction is an example of “a second side”. In the drawings described below, illustration of constitutions not related to the description may be omitted.

### First Embodiment

### 1. Constitution of Semiconductor Storage Device

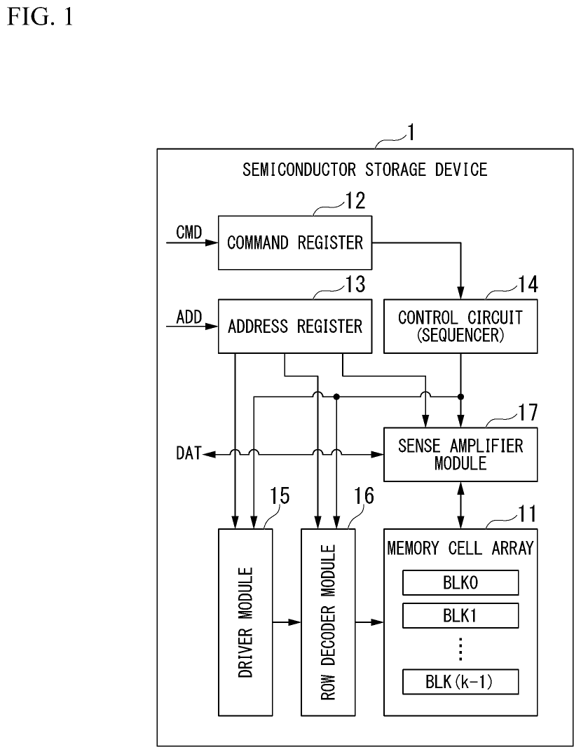

FIG. 1 is a block diagram showing a part of a semiconductor storage device 1 of a first embodiment. For example, the semiconductor storage device 1 is a non-volatile semiconductor storage device. The semiconductor storage device 1 is a NAND-type flash memory. The semiconductor storage device 1 can be connected to an external host device. The semiconductor storage device 1 is used as a storage space for the host device. For example, the semiconductor storage device 1 includes a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK(k−1) (k is an integer equal to or larger than 1). The blocks BLK are a set of memory cell transistors. The blocks BLK are used as units of data erasure. A plurality of bit lines and a plurality of word lines are provided in the memory cell array 11. Each of the memory cell transistors is associated with one bit line and one word line.

The command register 12 holds commands CMD received by the semiconductor storage device 1 from the host device. The address register 13 holds address information ADD received by the semiconductor storage device 1 from the host device. The address information ADD is used when selecting the block BLK, the word line, and the bit line. The control circuit 14 controls various operations of the semiconductor storage device 1. For example, the control circuit 14 executes writing operation, reading operation, erasing operation, or the like of data in accordance with the commands CMD held in the command register 12.

The driver module 15 includes a voltage generation circuit and generates voltages used in various operations of the semiconductor storage device 1. The row decoder module 16 transfers a voltage, which has been applied to a signal line corresponding to the selected word line, to the selected word line. In writing operation, the sense amplifier module 17 applies a desired voltage to each of the bit lines. In reading operation, the sense amplifier module 17 determines data stored in each of the memory cell transistors in accordance with the voltage of each of the bit lines. In this operation, the sense amplifier module 17 transfers determination results to the host device as reading data DAT.

### 2. Electrical Constitution of Memory Cell Array

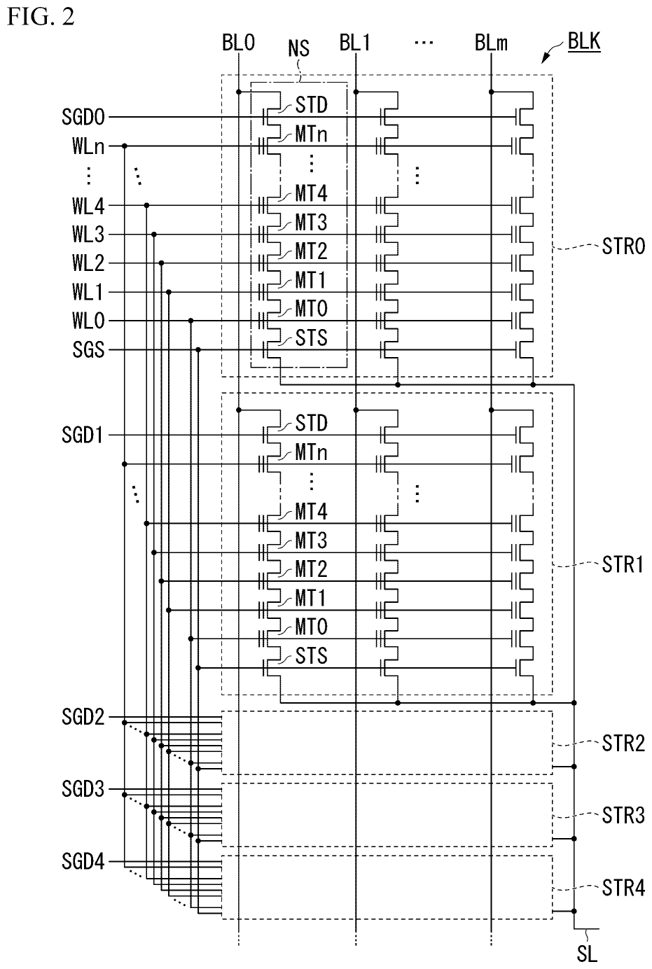

FIG. 2 is a view showing an equivalent circuit of a part of the memory cell array 11. FIG. 2 shows one block BLK included in the memory cell array 11. The block BLK includes a plurality of strings STR (for example, five strings STR0 to STR4).

Each of the strings STR includes a plurality of NAND strings NS which are respectively associated with bit lines BL0 to BLm (m is an integer equal to or larger than 1). Each of the NAND strings NS includes a plurality of memory cell transistors MT0 to MTn (n is an integer equal to or larger than 1), one or more drain-side selection transistors STD, and one or more source-side selection transistors STS.

In each of the NAND strings NS, the memory cell transistors MT0 to MTn are connected in series. Each of the memory cell transistors MT includes a control gate and a charge accumulation portion. The control gate of the memory cell transistor MT is connected to any of the word lines WL0 to WLn. In each of the memory cell transistors MT, charge is accumulated in the charge accumulation portion in response to the voltage applied to the control gate via the word line WL, and data is held in a non-volatile manner.

A drain of the drain-side selection transistor STD is connected to the bit line BL corresponding to the NAND string NS. A source of the drain-side selection transistor STD is connected to one end of each of the memory cell transistors MT0 to MTn connected in series. The control gate of the drain-side selection transistor STD is connected to any of drain-side selection gate lines SGD0 to SGD4. The drain-side selection transistor STD is electrically connected to the row decoder module 16 via the drain-side selection gate line SGD. When a predetermined voltage is applied to the corresponding drain-side selection gate line SGD, the drain-side selection transistor STD connects the NAND string NS and the bit line BL.

A drain of the source-side selection transistor STS is connected to the other end of each of the memory cell transistors MT0 to MTn connected in series. A source of the source-side selection transistor STS is connected to a source line SL. The control gate of the source-side selection transistor STS is connected to a source-side selection gate line SGS. When a predetermined voltage is applied to the source-side selection gate line SGS, the source-side selection transistor STS connects the NAND string NS and the source line SL.

In the same block BLK, the control gates of the memory cell transistors MT0 to MTn are respectively connected to the corresponding word lines WL0 to WLn in common. In the same string STR, the control gates of the drain-side selection transistors STD are respectively connected to the corresponding drain-side selection gate lines SGD in common. The control gates of the source-side selection transistors STS are respectively connected to the source-side selection gate lines SGS in common. In the memory cell array 11, the bit lines BL are shared by the NAND strings NS to which the same column address is assigned in the plurality of strings STR.

### 3. Structure of Semiconductor Storage Device

Next, a structure of the semiconductor storage device 1 will be described.

FIG. 3 is a cross-sectional view showing a part of the semiconductor storage device 1. For example, the semiconductor storage device 1 has a first chip 2 and a second chip 3. The second chip 3 is a chip adhered to the first chip 2.

### 3.1 First Chip

The first chip 2 is a circuit chip including a peripheral circuit. For example, the first chip 2 includes a semiconductor substrate 21, a peripheral circuit 22, an insulating portion 23, and a plurality of pads 24.

For example, the semiconductor substrate 21 is a substrate serving as a base of the first chip 2. At least a part of the semiconductor substrate 21 has a plate shape lying in the X direction and the Y direction. For example, the semiconductor substrate 21 is formed of a semiconductor material such as silicon.

The peripheral circuit 22 is a circuit for causing the memory cell array 11 described above to function. The peripheral circuit 22 includes a plurality of transistors 22a and a plurality of wirings 22b. The peripheral circuit 22 includes one or more of the command register 12, the address register 13, the control circuit 14, the driver module 15, the row decoder module 16, and the sense amplifier module 17 described above. The insulating portion 23 covers the peripheral circuit 22. The plurality of pads 24 are provided on a surface of the insulating portion 23. Each of the pads 24 is electrically connected to the peripheral circuit 22.

### 3.2 Second Chip

The second chip 3 is an array chip including the memory cell array 11. For example, the second chip 3 has the memory cell array 11, an insulating portion 31, and a plurality of pads 32. Here, the insulating portion 31 and the plurality of pads 32 will be described, and the memory cell array 11 will be described below.

The insulating portion 31 covers the memory cell array 11 from the side in the −Z direction. The plurality of pads 32 are provided on a surface of the insulating portion 31. Each of the pads 32 is electrically connected to a wiring (for example, a wiring 71 or a wiring 72) included in a wiring portion 70 of the memory cell array 11, which will be described below. In the present embodiment, the first chip 2 and the second chip 3 are integrated by adhering the plurality of pads 24 of the first chip 2 and the plurality of pads 32 of the second chip 3 facing each other.

### 4. Memory Cell Array

Next, the memory cell array 11 will be described.

As shown in FIG. 3, the memory cell array 11 includes an array region AR and a hookup region FR. A plurality of memory pillars MH (which will be described below) are provided in the array region AR. The array region AR is a region capable of storing data. A plurality of contacts CC (which will be described below) are provided in the hookup region FR. The hookup region FR is a region where a plurality of gate electrode layers 41 (which will be described below) and the wiring portion 70 are connected. For example, the hookup region FR is provided at each of both ends of the array region AR in the X direction.

As shown in FIG. 3, for example, the memory cell array 11 has the multi-layered body 40, the source lines SL, the plurality of memory pillars MH, the plurality of bit lines BL, a plurality of contacts CH for memory pillars, a plurality of contacts VY for memory pillars, the contacts CC for gate electrode layers, the wiring portion 70, supports HR, and a plurality of division portions 80 (refer to FIG. 4). The memory pillars MH will be described below.

### 4.1 Multi-Layered Body

For example, the multi-layered body 40 includes the plurality of gate electrode layers 41, a plurality of insulating layers 42, an insulating layer 43, and an insulating portion 44. The plurality of gate electrode layers 41 and the plurality of insulating layers 42 are alternately stacked one by one in the Z direction.

The gate electrode layers 41 lie in the X direction and the Y direction. Each of the gate electrode layers 41 contains a conductive material (for example, tungsten, molybdenum, or silicon doped with impurities).

One or more (for example, a plurality of) gate electrode layers 41 positioned above in the plurality of gate electrode layers 41 function as the source-side selection gate lines SGS. The source-side selection gate lines SGS are provided in common with respect to the plurality of memory pillars MH arranged in the X direction or the Y direction. The intersecting portions between the source-side selection gate lines SGS and a channel layer 52 (which will be described below) of each of the memory pillars MH function as the source-side selection transistors STS described above. The source-side selection gate line SGS is an example of “a first selection gate line”. The source-side selection transistor STS is an example of “a first selection transistor”.

One or more (for example, a plurality of) gate electrode layers 41 positioned below in the plurality of gate electrode layers 41 function as the drain-side selection gate lines SGD. The drain-side selection gate lines SGD are provided in common with respect to the plurality of memory pillars MH arranged in the X direction or the Y direction. The intersecting portions between the drain-side selection gate lines SGD and the channel layer 52 (which will be described below) of each of the memory pillars MH function as the drain-side selection transistors STD described above. The drain-side selection gate line SGD is an example of “a second selection gate line”. The drain-side selection transistor STD is an example of “a second selection transistor”.

In the plurality of gate electrode layers 41, at least a part of the remaining gate electrode layers 41 provided between the gate electrode layers 41 functioning as the source-side selection gate lines SGS and the drain-side selection gate lines SGD function as the word lines WL. The word lines WL are provided in common with respect to the plurality of memory pillars MH arranged in the X direction and the Y direction. In the present embodiment, the intersecting portions between the word lines WL and the channel layer 52 (which will be described below) of each of the memory pillars MH function as the memory cell transistors MT described above.

In the hookup region FR, lengths of the plurality of gate electrode layers 41 in the X direction differ from each other. For example, the lengths of the plurality of gate electrode layers 41 in the X direction increase as the gate electrode layers 41 are positioned closer to the side in the +Z direction. Accordingly, in the hookup region FR, end portions of the plurality of gate electrode layers 41 are disposed in a stepped shape.

The insulating layers 42 are interlayer insulating films which are provided between two gate electrode layers 41 adjacent to each other in the Z direction and insulate the two gate electrode layers 41. The insulating layers 42 lie in the X direction and the Y direction. For example, the insulating layers 42 are formed of a film containing silicon and oxygen (for example, a silicon oxide film).

The insulating layer 43 is an insulating layer provided above the gate electrode layer 41 disposed at the top. The insulating layer 43 is disposed between the gate electrode layer 41 disposed at the top and the source line SL. The insulating layer 43 is along in the X direction and the Y direction. For example, the insulating layer 43 is formed of a film containing silicon and oxygen (for example, a silicon oxide film). For example, the thickness of the insulating layer 43 in the Z direction is larger than the thickness of the insulating layer 42 in the Z direction.

The insulating portion 44 is an insulating portion provided in the hookup region FR. The insulating portion 44 covers the end portions of the plurality of gate electrode layers 41 disposed in a stepped shape from the side in the −Z direction. For example, the insulating portion 44 is formed using tetraethyl orthosilicate (TEOS (Si(OC₂H₅)₄).

### 4.2 Source Line

The source line SL is provided on the insulating layer 43. For example, the source line SL is a conductive layer or a semiconductor layer extending in the X direction and the Y direction. For example, the source line SL is formed of a conductive material such as tungsten or molybdenum or a semiconductor material containing silicon.

### 4.3 Bit Line

The bit line BL is a wiring for selecting one memory pillar MH from the plurality of memory pillars MH. The plurality of bit lines BL are disposed on the downward side (side in the −Z direction) with respect to the multi-layered body 40. The plurality of bit lines BL are arranged in the X direction with an interval therebetween in the X direction. Each of the bit lines BL extends in the Y direction. Each of the bit lines BL extends so as to pass through below the plurality of corresponding memory pillars MH.

Each of the bit lines BL is connected to the channel layer 52 of the memory pillar MH (which will be described below) via the contact VY and the contact CH. Accordingly, with a combination of the word line WL and the bit line BL, the memory cell transistor MT can be optionally selected from the plurality of memory cell transistors MT which are disposed three-dimensionally.

### 4.4 Contact for Gate Electrode Layer

The contact CC is an electrical connection portion electrically connecting the gate electrode layer 41 and the wiring 72 (which will be described below) included in the wiring portion 70. For example, the plurality of contacts CC are provided in the hookup region FR of the memory cell array 11. The plurality of contacts CC extend in the Z direction inside the multi-layered body 40 and are connected to the gate electrode layers 41 different from each other. The contacts CC have electrical conductivity. The contacts CC are formed of a conductive material (for example, tungsten, molybdenum, or silicon doped with impurities).

### 4.5 Wiring Portion

For example, the wiring portion 70 is disposed between the multi-layered body 40 and the semiconductor substrate 21. For example, the wiring portion 70 includes a plurality of wirings 71, a plurality of vias V1, and a plurality of wirings 72.

The wiring 71 is an electrical connection portion electrically connecting the bit line BL and the pad 32. For example, the plurality of wirings 71 are disposed below with respect to the plurality of bit lines BL. For example, each of the wirings 71 extends in the X direction or the Y direction. The vias V1 electrically connecting the wirings 71 and the bit lines BL are provided between the wirings 71 and the bit lines BL.

The wiring 72 is an electrical connection portion electrically connecting the contact CC for a conductive layer and the pad 32. The wiring 72 is electrically connected to the gate electrode layer 41 via the contact CC for a conductive layers. A voltage is applied to the wiring 72 in order to select the gate electrode layer 41 (the word line WL, the drain-side selection gate line SGD, or the source-side selection gate line SGS).

### 4.6 Support

The support HR is provided in the hookup region FR. The support HR penetrates the multi-layered body 40 in the Z direction. The support HR extends in the hookup region FR. For example, the support HR is formed of an insulation material. The support HR supports the plurality of insulating layers 42 such that they do not collapse during a replacement step (which will be described below) and the like.

### 4.7 Division Portion

Next, the division portion 80 will be described.

FIG. 4 is a cross-sectional view showing the semiconductor storage device 1 shown in FIG. 3 along line F4-F4. The plurality of division portions 80 are provided in the multi-layered body 40. The plurality of division portions 80 are disposed in a manner of being divided in the Y direction. Each of the plurality of division portions 80 extends in the Z direction inside the multi-layered body 40 and divides one or more gate electrode layers 41 including the lowermost layer of the plurality of gate electrode layers 41 in the Y direction. For example, the plurality of division portions 80 include a plurality of division portions ST and a plurality of division portions SHE.

### 4.7.1 Division Portion ST

The division portions ST are wall portions dividing the multi-layered body 40 in the Y direction. The plurality of division portions ST are disposed in a manner of being divided in the Y direction. The division portions ST extend in the Z direction and penetrate the multi-layered body 40. The division portions ST extend in the X direction. The division portions ST are wall portions lying in the X direction and the Z direction. The division portions ST divide each of all the gate electrode layers 41 included in the multi-layered body 40 in the Y direction.

### 4.7.2 Division Portion SHE

The division portions SHE are division portions having shorter lengths in the Z direction than the division portions ST and are wall portions dividing a lower end portion of the multi-layered body 40 in the Y direction. The plurality of division portions SHE are disposed in a manner of being divided in the Y direction. In the present embodiment, a plurality of (for example, four) division portions SHE are present between two division portions ST adjacent to each other in the Y direction. The division portions SHE are provided in the lower end portion of the multi-layered body 40. The division portions SHE extend in the Z direction halfway through the multi-layered body 40. The division portions SHE extend in the X direction. That is, the division portions SHE are wall portions lying in the X direction and the Z direction.

The division portions SHE penetrate a part of the gate electrode layers 41 including the lowermost layer of the plurality of gate electrode layers 41 and divide the part of the gate electrode layers 41 in the Y direction. For example, the division portions SHE penetrate each of all the gate electrode layers 41 functioning as the drain-side selection gate lines SGD. On the other hand, the division portions SHE do not reach the gate electrode layers 41 functioning as the word lines WL. The division portions SHE divide only the gate electrode layers 41 functioning as the drain-side selection gate lines SGD in the Y direction. For example, the division portions SHE are formed of a film containing silicon and oxygen (for example, a silicon oxide film).

### 5. Memory Pillar

Next, the memory pillar MH will be described.

The plurality of memory pillars MH are arranged in the X direction and the Y direction. Each of the memory pillars MH extends in the Z direction inside the multi-layered body 40 and penetrates the multi-layered body 40. The memory pillar MH is an example of “a columnar body”.

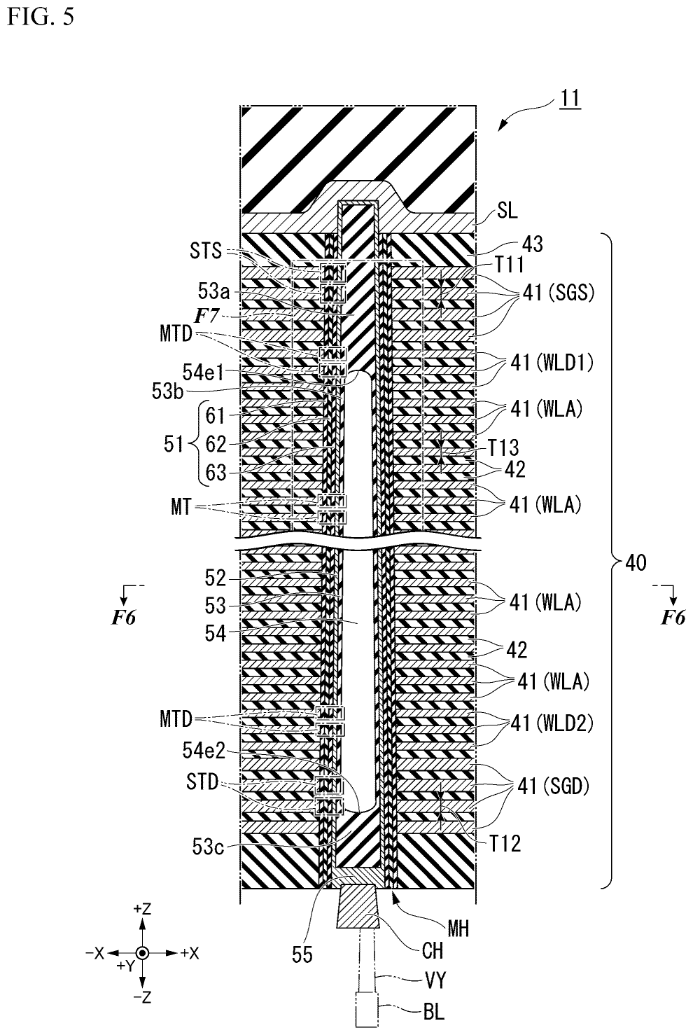

FIG. 5 is an enlarged cross-sectional view showing a region surrounded by line F5 in the memory cell array 11 shown in FIG. 3. For example, the memory pillar MH has a memory film (multilayer film) 51, the channel layer 52, an insulating portion 53, a cavity portion (air gap) 54, and a cap portion 55.

The memory film 51 is disposed in an outer circumferential portion of the memory pillar MH. The memory film 51 extends in the Z direction. For example, the memory film 51 is provided over the entire length of the memory pillar MH in the Z direction except for the upper end portion of the memory pillar MH. The memory film 51 is positioned between the plurality of gate electrode layers 41 and the channel layer 52. For example, the memory film 51 includes a block insulating film 61, a charge trapping film 62, and a tunnel insulating film 63.

The block insulating film 61 is disposed in the outermost circumferential portion of the memory pillar MH. The block insulating film 61 is provided between the plurality of gate electrode layers 41 and the charge trapping film 62. The block insulating film 61 is an insulating film for suppressing back-tunneling. Back-tunneling is a phenomenon in which charge returns from the word line WL to the charge trapping film 62. The block insulating film 61 is formed to have an annular shape extending in the Z direction. For example, the block insulating film 61 is provided over the entire length of the memory pillar MH in the Z direction except for the upper end portion of the memory pillar MH. For example, the block insulating film 61 is a multi-layered structure film in which a plurality of insulating films such as films containing silicon and oxygen or films containing metal and oxygen are stacked. An aluminum oxide film is an example of a film containing metal and oxygen. The block insulating film 61 may contain a material having a high dielectric constant (high-k material), such as silicon nitride or hafnium oxide. The block insulating film 61 is an example of “a first insulating film”.

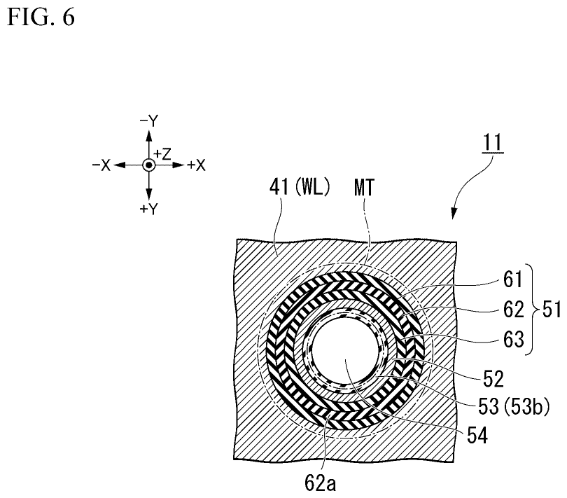

The charge trapping film 62 is provided on the inner circumferential side of the block insulating film 61 in the X direction and the Y direction. The charge trapping film 62 is positioned between the block insulating film 61 and the tunnel insulating film 63. The charge trapping film 62 is formed to have an annular shape, extends in the Z direction. For example, the charge trapping film 62 is provided over the entire length of the memory pillar MH in the Z direction except for the upper end portion of the memory pillar MH. The charge trapping film 62 is a functional film having many crystal defects (trapping levels) and is capable of trapping charge in the crystal defects. For example, the charge trapping film 62 is formed of a film containing silicon and nitrogen. In the charge trapping film 62, a part 62a adjacent to each of the word lines WL (refer to FIG. 6) is an example of “a charge accumulation portion” capable of storing information by accumulating charge.

The tunnel insulating film 63 is provided on the inner circumferential side of the charge trapping film 62 in the X direction and the Y direction. The tunnel insulating film 63 is provided between the charge trapping film 62 and the channel layer 52. For example, the tunnel insulating film 63 has an annular shape along the outer circumferential surface of the channel layer 52. The tunnel insulating film 63 extends in the Z direction along the channel layer 52. For example, the tunnel insulating film 63 is provided over the entire length of the memory pillar MH in the Z direction except for the upper end portion of the memory pillar MH. The tunnel insulating film 63 is a potential barrier between the charge trapping film 62 and the channel layer 52. The tunnel insulating film 63 is formed of a film containing silicon and oxygen or a film containing silicon, oxygen, and nitrogen. The tunnel insulating film 63 is an example of “a second insulating film”.

The channel layer 52 is provided on the inner circumferential side of the memory film 51 in the X direction and the Y direction. The channel layer 52 is formed to have an annular shape. The channel layer 52 extends in the Z direction. For example, the channel layer 52 is provided over the entire length of the memory pillar MH in the Z direction. The channel layer 52 is formed of a semiconductor material such as polysilicon. The channel layer 52 may be doped with impurities. When voltages are applied to the word lines WL, the channel layer 52 forms a channel and electrically connects the bit line BL and the source line SL. The channel layer 52 is an example of “a semiconductor film”.

FIG. 6 is a cross-sectional view showing the memory cell array 11 shown in FIG. 5 along line F6-F6. Due to the constitution described above, metal-Al-nitride-oxide-silicon (MANOS) type memory cell transistors MT are formed at the same height as the respective word lines WL by the edge portions of the word lines WL adjacent to the memory pillar MH, the block insulating film 61, the charge trapping film 62, the tunnel insulating film 63, and the channel layer 52. In place of the charge trapping film 62, the memory film 51 may have a floating gate-type charge accumulation portion (floating gate electrode) as a charge accumulation portion. For example, the floating gate-type charge accumulation portion is formed of polysilicon containing impurities.

Returning to FIG. 5, the remaining constitution of the memory pillar MH will be described.

The insulating portion 53 is provided on the inner circumferential side of the channel layer 52 in the X direction and the Y direction. The insulating portion 53 fills at least a part inside the channel layer 52. The insulating portion 53 is formed of a film containing silicon and oxygen (for example, a silicon oxide film). The insulating portion 53 extends in the Z direction. For example, the insulating portion 53 is provided over the entire length of the memory pillar MH in the Z direction except for the lower end portion of the memory pillar MH.

The cavity portion 54 is provided inside a part of the insulating portion 53. For example, in a part of the insulating portion 53 in the Z direction, the cavity portion 54 is provided on the inner circumferential side of the insulating portion 53 in the X direction and the Y direction. The cavity portion 54 is adjacent to at least a part of the insulating portion 53 in the Z direction.

The cap portion 55 is provided below the insulating portion 53. The cap portion 55 is a semiconductor portion formed of a semiconductor material such as amorphous silicon or polysilicon. For example, the cap portion 55 is doped with impurities. The cap portion 55 is disposed on the inner circumferential side of the lower end portion of the memory film 51 and is formed integrally with the channel layer 52. The cap portion 55 forms the lower end portion of the memory pillar MH together with the lower end portion of the channel layer 52. The contact CH comes into contact with the cap portion 55 from the side in the −Z direction.

### 6. Disposition of Gate Electrode Layers

Next, disposition of the gate electrode layers 41 will be described.

As shown in FIG. 5, a plurality of gate electrode layers 41 include a plurality of (for example, four) source-side selection gate lines SGS, a plurality of (for example, four) drain-side selection gate lines SGD, and a plurality of word lines WL. For example, thicknesses T11 of the source-side selection gate lines SGS in the Z direction are larger than thicknesses T13 of the word lines WL in the Z direction. The thicknesses T12 of the drain-side selection gate lines SGD in the Z direction are larger than the thicknesses T13 of the word lines WL in the Z direction. The thicknesses T11 of the source-side selection gate lines SGS in the Z direction may be the same as the thicknesses T13 of the word lines WL in the Z direction. The thicknesses T12 of the drain-side selection gate lines SGD in the Z direction may be the same as the thicknesses T13 of the word lines WL in the Z direction.

For example, among the plurality of gate electrode layers 41 described above, the plurality of source-side selection gate lines SGS are a group of the gate electrode layers 41 which are positioned in the end portion of the multi-layered body 40 on the side in the +Z direction and to which voltages are applied at the same timing. Among the plurality of gate electrode layers 41 described above, the drain-side selection gate lines SGD are a group of the gate electrode layers 41 which are positioned in the end portion of the multi-layered body 40 on the side in the −Z direction and to which voltages are applied at the same timing.

For example, the drain-side selection gate lines SGD are the gate electrode layers 41 to which lower voltages (for example, voltages equal to or lower than half) are applied during writing operation with respect to the memory cell transistors MT compared to data word lines WLA (which will be described below) corresponding to unselected memory cell transistors MT (memory cell transistors MT which are not writing targets). The drain-side selection gate lines SGD may be set to 0 V during writing operation with respect to the memory cell transistors MT when an operation mode in which the channel layer 52 and the source line SL of the memory pillar MH are electrically connected is applied during writing operation with respect to the memory cell transistors MT.

For example, the source-side selection gate lines SGS are gate electrode layers 41 which are set to 0 V during writing operation with respect to the memory cell transistors MT. Voltages equal to or lower than half may be applied to the source-side selection gate lines SGS compared to the data word lines WLA (which will be described below) corresponding to the unselected memory cell transistors MT (memory cell transistors MT which are not writing targets) when the operation mode in which the channel layer 52 and the source line SL of the memory pillar MH are electrically connected is applied during writing operation with respect to the memory cell transistors MT.

The plurality of word lines WL include a plurality of (for example, five or fewer) first dummy word lines WLD1, a plurality of (for example, five or fewer) second dummy word lines WLD2, and a plurality of data word lines WLA.

In this application, “dummy word lines” are the word lines WL forming the memory cell transistors MT functioning as dummy memory cell transistors MTD in intersecting portions the memory pillar MH. The dummy memory cell transistors MTD are transistors which have the same constitution as the memory cell transistors MT used for retaining valid data but are not used for retaining valid data. For example, the dummy memory cell transistors MTD are disposed in order to suppress an influence of operation of applying voltages to the source-side selection gate lines SGS or the drain-side selection gate lines SGD during certain writing operation on unselected memory cell transistors MT (memory cell transistors MT which are not writing targets).

In the example shown in FIG. 5, the plurality of word lines WL have five or fewer (for example, three) first dummy word lines WLD1 as a predetermined number of first dummy word lines WLD1 closest to the plurality of source-side selection gate lines SGS among the plurality of word lines WL. The first dummy word line WLD1 is an example of “a first word line”.

Similarly, the plurality of word lines WL have five or fewer (for example, three) second dummy word lines WLD2 as a predetermined number of second dummy word lines WLD2 closest to the plurality of drain-side selection gate lines SGD among the plurality of word lines WL. The second dummy word line WLD2 is an example of “a second word line”.

Each of the remaining word lines WL among the plurality of word lines WL is a data word line WLA forming the memory cell transistor MT used for retaining valid data. The data word line WLA positioned on the uppermost side among the plurality of data word lines WLA is a word line WL positioned immediately below the first dummy word line WLD1 on the lowermost side. The data word line WLA positioned on the lowermost side among the plurality of data word lines WLA is a word line WL positioned immediately above the second dummy word line WLD2 on the uppermost side. The data word line WLA is an example of “a third word line”.

When the memory pillar MH has a constitution of a plurality of stages in the Z direction (for example, when a first memory pillar MH and a second memory pillar MH disposed below the first memory pillar MH are connected in the Z direction), the word lines WL positioned near a connection portion between the memory pillars MH may be provided as the dummy word lines. In this case, the dummy word line positioned near the connection portion between the memory pillars MH corresponds to another example of “the third word line”.

### 7. Structure of Insulating Portion of Memory Pillar

Next, a structure of the insulating portion 53 of the memory pillar MH will be described.

As shown in FIG. 5, for example, the insulating portion 53 includes a first insulating portion 53a, a second insulating portion 53b, and a third insulating portion 53c.

### 7.1 First Insulating Portion

The first insulating portion 53a is positioned in the uppermost portion among the first to third insulating portions 53a, 53b, and 53c. In the present embodiment, the first insulating portion 53a is a part positioned above the cavity portion 54. In the present embodiment, the first insulating portion 53a is a solid part filling the inner circumferential side of the channel layer 52.

The first insulating portion 53a is adjacent to a plurality of (for example, all) source-side selection gate lines SGS in the X direction and the Y direction. In addition, in the present embodiment, the first insulating portion 53a is adjacent to a part (for example, two) of the first dummy word lines WLD1 among the plurality of (for example, three) first dummy word lines WLD1 in the X direction and the Y direction. On the other hand, the first insulating portion 53a is not adjacent to another part (for example, one on the lowermost side) of the first dummy word lines WLD1 of the plurality of (for example, three) first dummy word lines WLD1 in the X direction and the Y direction.

Instead of the foregoing example, the first insulating portion 53a may be adjacent to all the first dummy word lines WLD1 in the X direction and the Y direction. On the other hand, the first insulating portion 53a may not be adjacent to all the first dummy word lines WLD1 in the X direction and the Y direction.

### 7.2 Second Insulating Portion

The second insulating portion 53b is positioned in the middle among the first to third insulating portions 53a, 53b, and 53c. In the present embodiment, the second insulating portion 53b is a part adjacent to the cavity portion 54 in the X direction and the Y direction. In the present embodiment, the second insulating portion 53b is a hollow part in which the cavity portion 54 is provided. The second insulating portion 53b has a toric shape along the inner circumferential surface of the channel layer 52.

The second insulating portion 53b is adjacent to a plurality of (for example, all) data word lines WLA in the X direction and the Y direction. In addition, in the present embodiment, the second insulating portion 53b is adjacent to a part (for example, one on the lowermost side) of the first dummy word lines WLD1 among the plurality of (for example, three) first dummy word lines WLD1 described above in the X direction and the Y direction.

The second insulating portion 53b is adjacent to a plurality of (for example, all) second dummy word lines WLD2 in the X direction and the Y direction. The second insulating portion 53b may not be adjacent to a part or all of the second dummy word lines WLD2 among the plurality of second dummy word lines WLD2 in the X direction and the Y direction.

The second insulating portion 53b is adjacent to a part (for example, three) of the drain-side selection gate lines SGD among the plurality of (for example, four) drain-side selection gate lines SGD in the X direction and the Y direction. On the other hand, the second insulating portion 53b is not adjacent to another part (for example, one on the lowermost side) of the drain-side selection gate lines SGD among the plurality of (for example, four) drain-side selection gate lines SGD in the X direction and the Y direction.

Instead of the foregoing example, the second insulating portion 53b may be adjacent to all the drain-side selection gate lines SGD in the X direction and the Y direction. On the other hand, the second insulating portion 53b may not be adjacent to all the drain-side selection gate lines SGD in the X direction and the Y direction.

In addition, the second insulating portion 53b may be partially interrupted in the middle in the Z direction. In other words, a part of the channel layer 52 may be exposed to the cavity portion 54 at a position adjacent to a part of the word lines WL in the X direction and the Y direction.

### 7.3 Third Insulating Portion

The third insulating portion 53c is positioned in the lowermost portion among the first to third insulating portions 53a, 53b, and 53c. In the present embodiment, the third insulating portion 53c is a part positioned below the cavity portion 54. In the present embodiment, the third insulating portion 53c is a solid part filling the inner circumferential side of the channel layer 52.

The third insulating portion 53c is adjacent to a part (for example, one on the lowermost side) of the drain-side selection gate lines SGD among the plurality of (for example, four) drain-side selection gate lines SGD in the X direction and the Y direction. The third insulating portion 53c may be adjacent to all the drain-side selection gate lines SGD in the X direction and the Y direction. The third insulating portion 53c is not an essential constituent element and may be omitted.

### 7.4 Cavity Portion

The cavity portion 54 has a first end 54e1 and a second end 54e2. The first end 54e1 is an end (upper end) on the side in the +Z direction. The second end 54e2 is another end (lower end) on the side in the −Z direction.

In the present embodiment, the first end 54e1 corresponds to a boundary portion between the first insulating portion 53a and the second insulating portion 53b. In the present embodiment, the first end 54e1 is positioned at the same height as a region where a plurality of first dummy word lines WLD1 are provided. For example, the region where the first dummy word lines WLD1 are provided may be a region between a position where the first dummy word line WLD1 at the bottom is provided and a position where the first dummy word line WLD1 at the top is provided among the plurality of first dummy word lines WLD1. For example, the first end 54e1 is positioned on the side in the −Z direction from a plurality of (for example, all) source-side selection gate lines SGS. For example, the first end 54e1 is positioned on the side in the −Z direction from one word line WL (for example, one first dummy word line WLD1) positioned on the side in the −Z direction from the plurality of source-side selection gate lines SGS among the plurality of word lines WL.

In the present embodiment, the second end 54e2 corresponds to a boundary portion between the second insulating portion 53b and the third insulating portion 53c. In the present embodiment, the second end 54e2 is positioned at the same height as a region where a plurality of drain-side selection gate lines SGD are provided. The region where the drain-side selection gate lines SGD are provided may be a region between a position where the drain-side selection gate line SGD at the bottom is provided and a position where the drain-side selection gate line SGD at the top is provided among the plurality of drain-side selection gate lines SGD.

In the present embodiment, the second end 54e2 is positioned on the side in the −Z direction from a plurality of (for example, all) second dummy word lines WLD2. For example, the second end 54e2 is positioned on the side in the −Z direction from one drain-side selection gate line SGD positioned on the side in the −Z direction from the plurality of second dummy word lines WLD2 among the plurality of drain-side selection gate lines SGD.

Instead of the foregoing example, the second end 54e2 may be positioned at the same height as a region where a plurality of second dummy word lines WLD2 are provided. For example, the region where the second dummy word lines WLD2 are provided may be a region between a position where the dummy word line WLD2 at the bottom is provided and a position where the dummy word line WLD2 at the top is provided among the plurality of second dummy word lines WLD2. In addition, in another example, the position of the second end 54e2 in the Z direction may be a position between the second dummy word line WLD2 at the bottom and the drain-side selection gate line SGD at the top.

Moreover, instead of the foregoing example, the second end 54e2 may be positioned on the side in the +Z direction in FIG. 5 further from the region where the plurality of second dummy word lines WLD2 are provided. For example, the second end 54e2 may be positioned on the side in the +Z direction from the second dummy word line WLD2 at the top (the second dummy word line WLD2 positioned on the farthest side in the +Z direction) among the plurality of second dummy word lines WLD2. For example, the second end 54e2 may be positioned between the second dummy word line WLD2 at the top among the plurality of second dummy word lines WLD2 and the word line WL within tenth counting from the second dummy word line WLD2 at the top to the side in the +Z direction. For example, the second end 54e2 may be positioned between the second dummy word line WLD2 at the top among the plurality of second dummy word lines WLD2 and the word line WL within fifth counting from the second dummy word line WLD2 at the top to the side in the +Z direction.

### 7.5 Dimensional Relationship of Insulating Portion

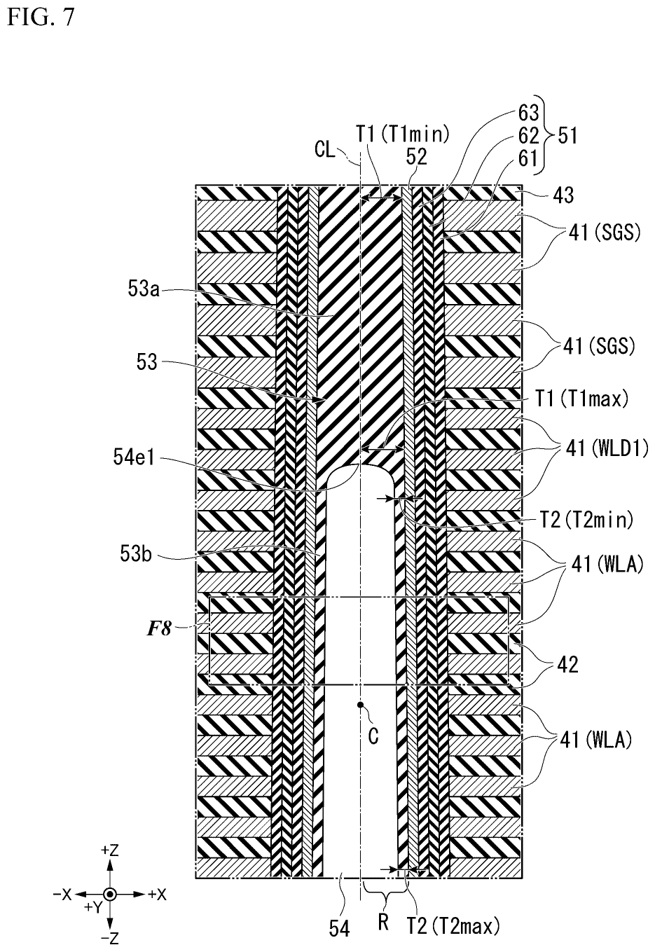

FIG. 7 is an enlarged cross-sectional view showing a region surrounded by line F7 in the memory cell array 11 shown in FIG. 5. Here, a centerline CL of the memory pillar MH will be defined. The centerline CL is a virtual centerline extending in the Z direction through a center C of the memory pillar MH in the X direction in a cross section in the X direction and the Z direction.

In the present embodiment, when a region R between the centerline CL and the channel layer 52 is viewed in a cross section in the X direction and the Z direction, a thickness T2 of the second insulating portion 53b in the X direction is smaller than a thickness T1 of the first insulating portion 53a in the X direction.

In this application, “the thickness of the first insulating portion” and “the thickness of the second insulating portion” are considered to exclude thicknesses of parts whose thickness suddenly changes compared to other parts such as the boundary portion between the first insulating portion 53a and the second insulating portion 53b. In addition, in this application, “the thickness of the second insulating portion” is considered to exclude thicknesses of parts close to the connection portion between the memory pillars MH (for example, parts adjacent to five word lines WL on the upward side and five word lines WL on the downward side close to the connection portion between the memory pillars MH in the X direction) when the memory pillars MH have a constitution of a plurality of stages in the Z direction.

In the present embodiment, when the region R is viewed, a maximum thickness T2max of the second insulating portion 53b in the X direction is smaller than a maximum thickness T1max of the first insulating portion 53a in the X direction. In addition, when the region R is viewed, a minimum thickness T2min of the second insulating portion 53b in the X direction is smaller than a minimum thickness T1min of the first insulating portion 53a in the X direction. Furthermore, when the region R is viewed, the maximum thickness T2max of the second insulating portion 53b in the X direction is smaller than the minimum thickness T1min of the first insulating portion 53a in the X direction.

For the sake of convenience of description, “the maximum thickness T1max” and “the maximum thickness T2max” are shown in FIG. 7, but the part where the thickness of the first insulating portion 53a becomes maximum or the part where the thickness of the second insulating portion 53b becomes maximum is not limited to the shown positions. Similarly, for the sake of convenience of description, “the minimum thickness T1min” and “the minimum thickness T2min” are shown in FIG. 7, but the part where the thickness of the first insulating portion 53a becomes minimum or the part where the thickness of the second insulating portion 53b becomes minimum is not limited to the shown positions.

In the present embodiment, the second insulating portion 53b extends in the Z direction in a manner of being adjacent to all the data word lines WLA. Furthermore, when the region R is viewed, the thickness T2 of the second insulating portion 53b in the X direction is smaller than the thickness T1 of the first insulating portion 53a in the X direction (for example, the minimum thickness T1min) over the entire length of the second insulating portion 53b in the Z direction.

In the present embodiment, when the region R is viewed, the maximum thickness T2max of the second insulating portion 53b in the X direction is smaller than the minimum thickness T1min of the first insulating portion 53a in the X direction. For the sake of convenience of description, “the maximum thickness T2max” is shown in FIG. 7, but the part where the thickness of the second insulating portion 53b becomes maximum is not limited to the shown position. For example, the thickness of the second insulating portion 53b can become maximum in the end portion of the second insulating portion 53b on the side in the −Z direction.

In the present embodiment, when the region R is viewed, the thickness T2 of the second insulating portion 53b in the X direction (for example, the maximum thickness T2max) is equal to or smaller than half the thickness T1 of the first insulating portion 53a in the X direction (for example, the maximum thickness T1max). From another viewpoint, when the region R is viewed, the minimum thickness T2min of the second insulating portion 53b in the X direction is equal to or smaller than half the minimum thickness T1min of the first insulating portion 53a in the X direction.

### 7.6 Dimensional Relationship Between Insulating Layer and Other Functional Layers

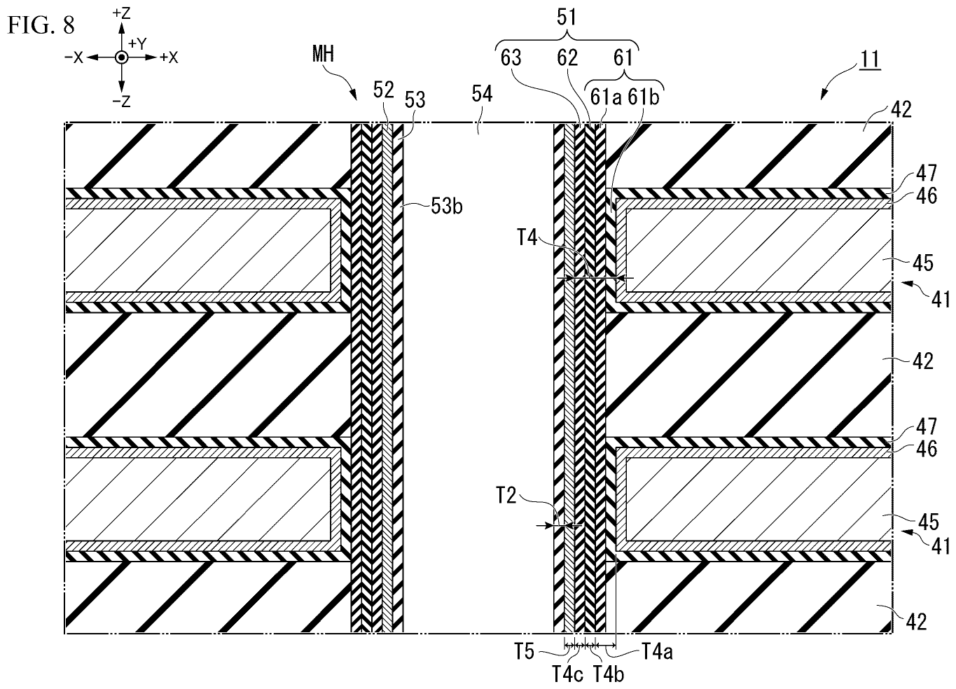

FIG. 8 is an enlarged cross-sectional view showing a region surrounded by line F8 in the memory cell array 11 shown in FIG. 7. In the present embodiment, for example, each of the gate electrode layers 41 includes a conductive portion 45, a barrier metal film 46, and an insulating film 47.

The conductive portion 45 is a part forming a main portion of the gate electrode layer 41. The conductive portion 45 extends in the X direction and the Y direction in a layered shape. The conductive portion 45 contains a conductive material (for example, tungsten, molybdenum, or silicon doped with impurities) described above.

The barrier metal film 46 is a film for suppressing diffusion of a conductive material contained in the conductive portion 45. For example, the barrier metal film 46 contains a material containing titanium, a material containing titanium and nitrogen, a material containing tantalum, a material containing tantalum and nitrogen, a material containing tungsten and nitrogen, or the like. The barrier metal film 46 is provided along a surface of the conductive portion 45. The barrier metal film 46 is provided between the conductive portion 45 and the insulating film 47. A part of the barrier metal film 46 extends in the Z direction along an edge portion of the conductive portion 45 facing the memory pillar MH and is positioned between the conductive portion 45 and the memory pillar MH.

The insulating film 47 is an insulating film for improving the pressure resistance of the gate electrode layer 41. For example, the insulating film 47 is formed of a film containing aluminum and oxygen (for example, an aluminum oxide film). The insulating film 47 is provided along a surface of the barrier metal film 46. The insulating film 47 is provided along a surface of the gate electrode layer 41. A part of the insulating film 47 extends in the Z direction along an edge portion of the barrier metal film 46 facing the memory pillar MH and is positioned between the barrier metal film 46 and the memory pillar MH.

In the present embodiment, the block insulating film 61 includes a first part 61a and second parts 61b. The first part 61a is formed to have an annular shape along the outer circumference of the charge trapping film 62. The first part 61a extends in the Z direction. For example, the first part 61a is provided over the entire length of the memory pillar MH in the Z direction except for the upper end portion of the memory pillar MH.

On the other hand, the second parts 61b are formed of parts of the insulating films 47 of the plurality of gate electrode layers 41. The second parts 61b are formed to have an annular shape along the outer circumference of the first part 61a of the block insulating film 61 and are present correspondingly to the heights at which the gate electrode layers 41 are disposed. In the present embodiment, the block insulating film 61 is formed by the first part 61a and the second parts 61b.

In the present embodiment, the thickness T2 of the second insulating portion 53b in the X direction is smaller than a thickness T4 of the memory film 51 in the X direction. For example, the thickness T2 of the second insulating portion 53b in the X direction is smaller than a thickness T4a of the block insulating film 61 in the X direction. “The thickness of the block insulating film 61 in the X direction” is the sum of the thickness of the first part 61a of the block insulating film 61 in the X direction and the thickness of the second parts 61b of the block insulating film 61 in the X direction.

From another viewpoint, the thickness T2 of the second insulating portion 53b in the X direction is smaller than the sum of a thickness T4b of the charge trapping film 62 in the X direction and a thickness T4c of the tunnel insulating film 63 in the X direction. From another viewpoint, the thickness T2 of the second insulating portion 53b in the X direction is smaller than the sum of the thickness T4b of the charge trapping film 62 in the X direction and a thickness T5 of channel layer 52 in the X direction. From another viewpoint, the thickness T2 of the second insulating portion 53b in the X direction is smaller than the sum of the thickness T4c of the tunnel insulating film 63 in the X direction and the thickness T5 of channel layer 52 in the X direction.

In the present embodiment, the minimum thickness T2min of the second insulating portion 53b in the X direction is equal to or smaller than 10 nm. In other words, the thickness T2 of at least a part of the second insulating portion 53b in the X direction is equal to or smaller than 10 nm.

In the present embodiment, the average thickness of the second insulating portion 53b in the X direction is equal to or smaller than 10 nm. In this application, “the average thickness of the second insulating portion” is the average value of the thicknesses of the second insulating portion 53b obtained by dividing the entire length of the second insulating portion 53b in the Z direction into five equal sections, for example, and measuring the thickness at five locations.

In addition, in the present embodiment, the maximum thickness T2max of the second insulating portion 53b in the X direction is equal to or smaller than 10 nm. In other words, the thickness T2 of the second insulating portion 53b in the X direction is equal to or smaller than 10 nm over the entire length of the second insulating portion 53b in the Z direction.

### 7.7 Impurity Concentration of Insulating Portion

Next, the impurity concentration of the insulating portion 53 will be described. Impurities are implanted into the insulating portion 53. For example, impurities are donor impurities (elements having more valence electrons than tetravalent elements, for example, pentavalent elements). For example, impurities are phosphorus (P), but they are not limited to this.

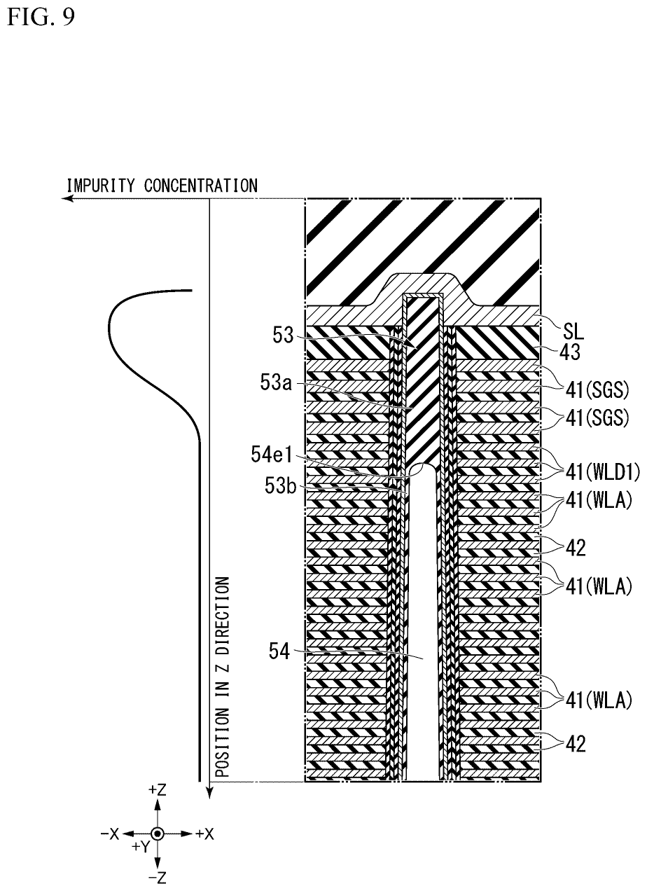

FIG. 9 is a view showing a profile of an impurity concentration (for example, a phosphorus concentration) in the insulating portion 53. In the present embodiment, the impurity concentration in the first insulating portion 53a is higher than the impurity concentration in the second insulating portion 53b. In the present embodiment, in the first insulating portion 53a, the concentration of impurities in the Z direction changes sharply. For example, when viewed in a direction traveling toward the side in the −Z direction, the rate of decrease in impurity concentration in the first insulating portion 53a is higher than the rate of decrease in impurity concentration in the second insulating portion 53b. For example, the rate of decrease in impurity concentration in the first insulating portion 53a is equal to twice or higher than the rate of decrease in impurity concentration in the second insulating portion 53b.

Here, when change in concentration of impurities in the first insulating portion 53a in the Z direction is significant, a gate-induced drain leakage (GIDL) current generated using the source-side selection gate lines SGS can be increased. If the GIDL current can be increased, it is easy to perform erasing operation of erasing data stored in the memory cell transistors MT.

### 8. Manufacturing Method

Next, a method of manufacturing the semiconductor storage device 1 will be described.

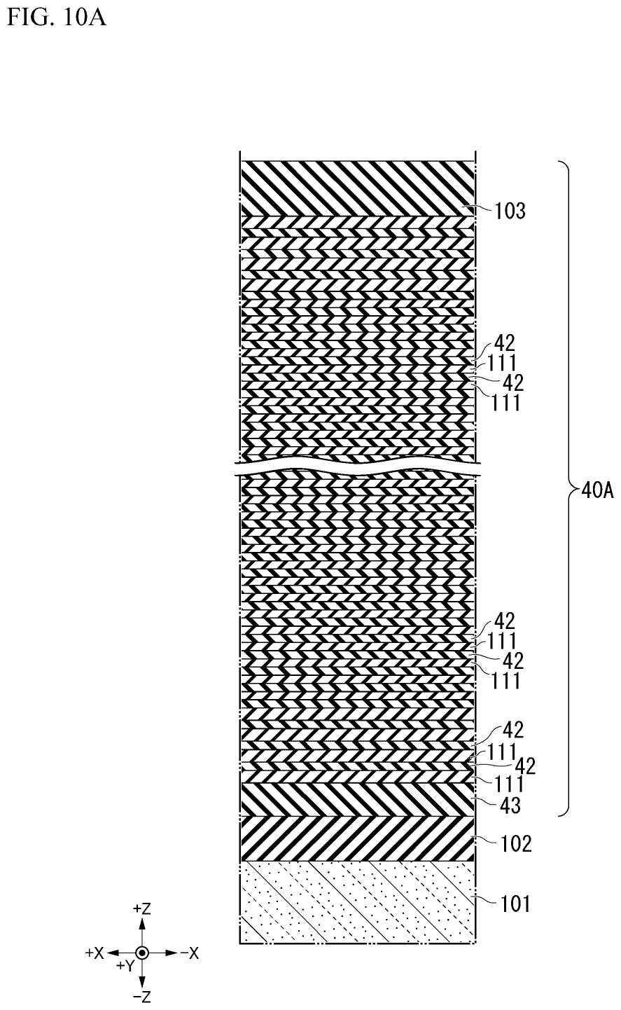

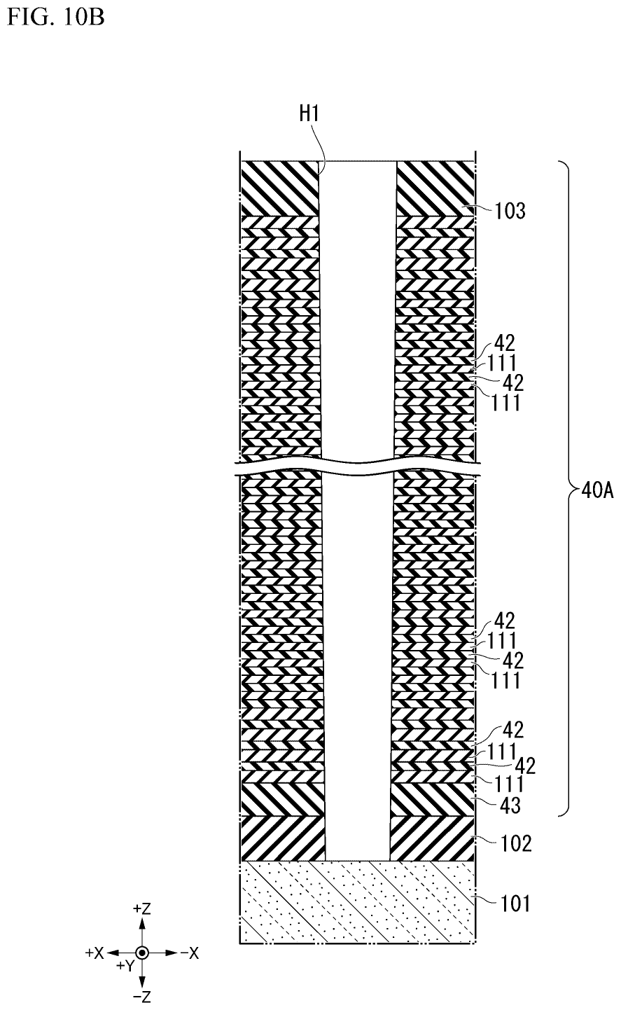

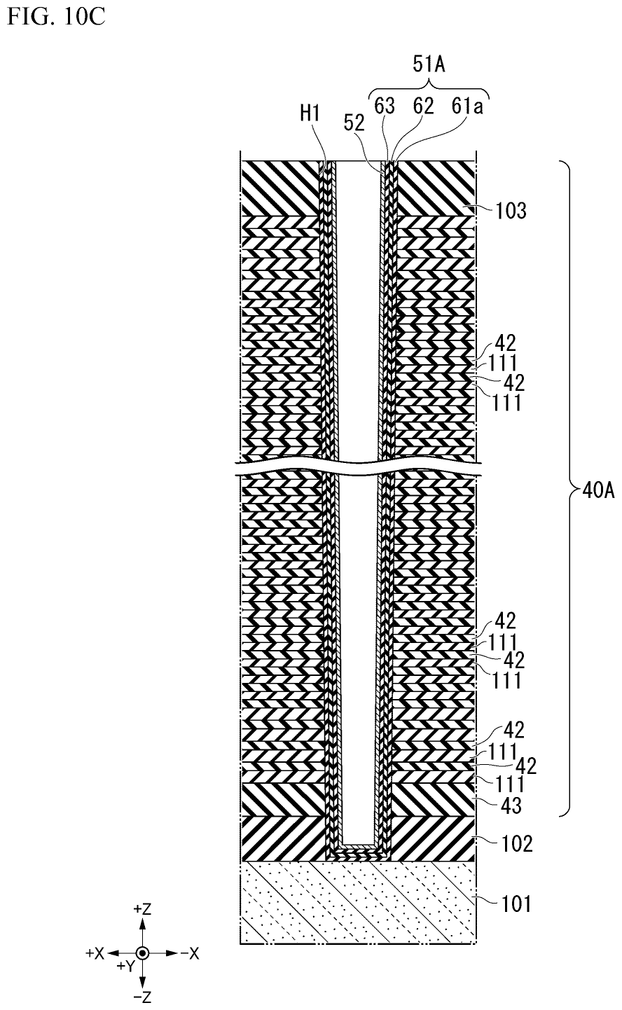

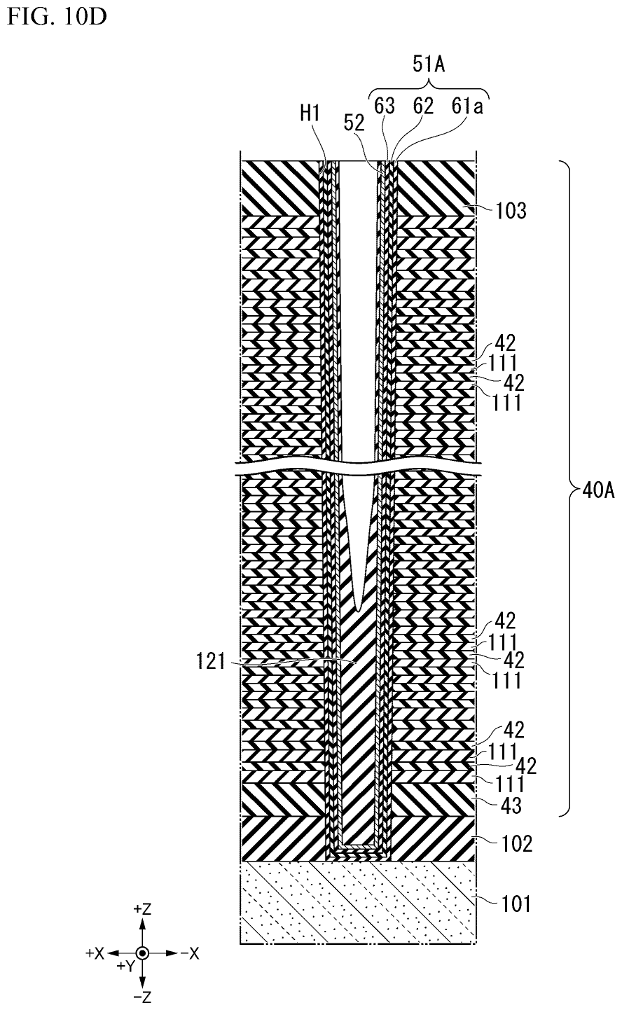

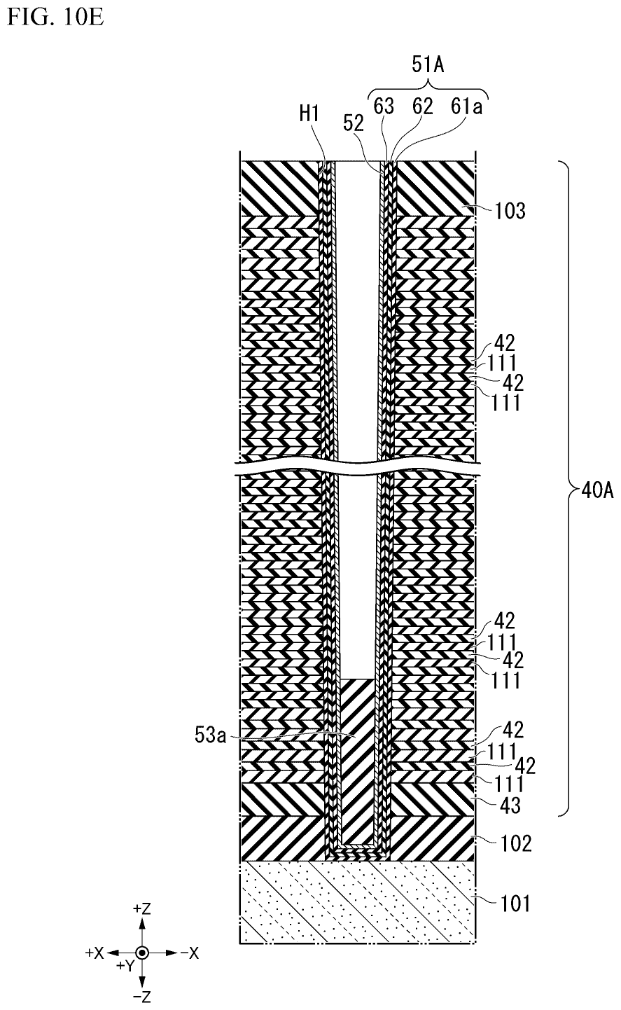

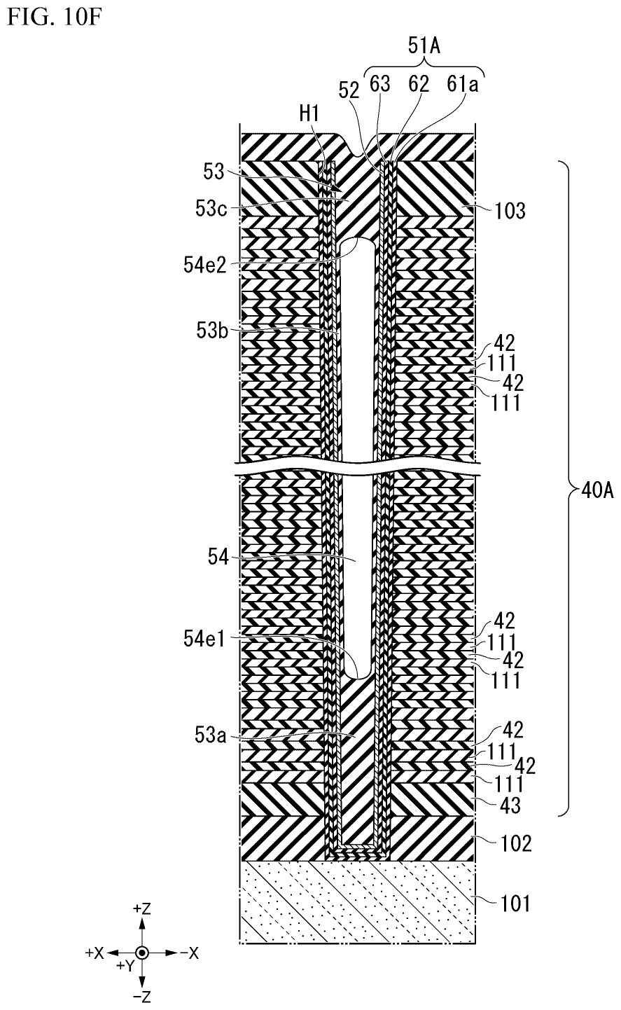

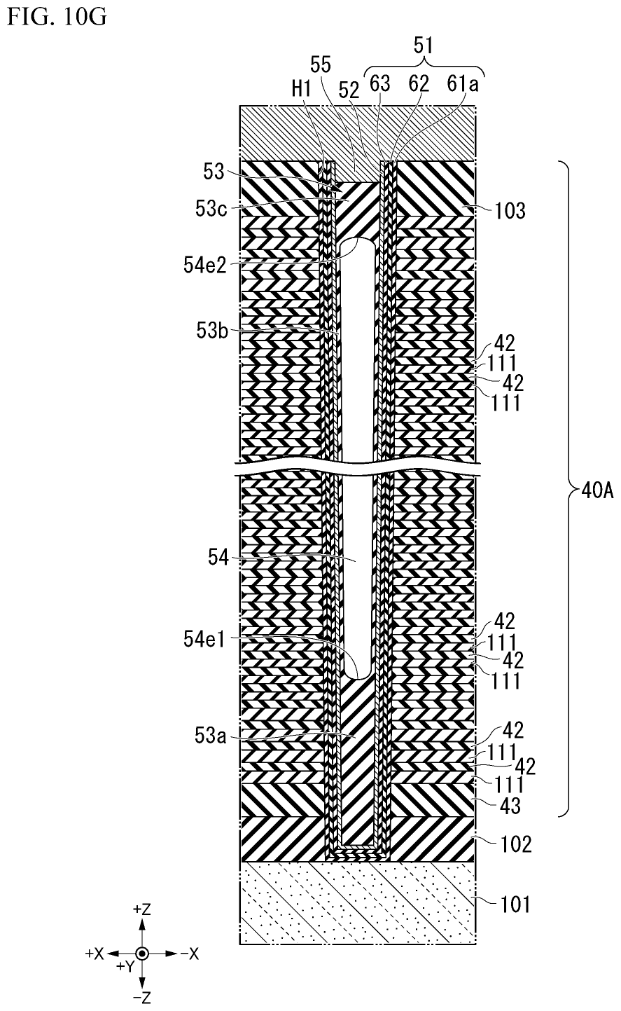

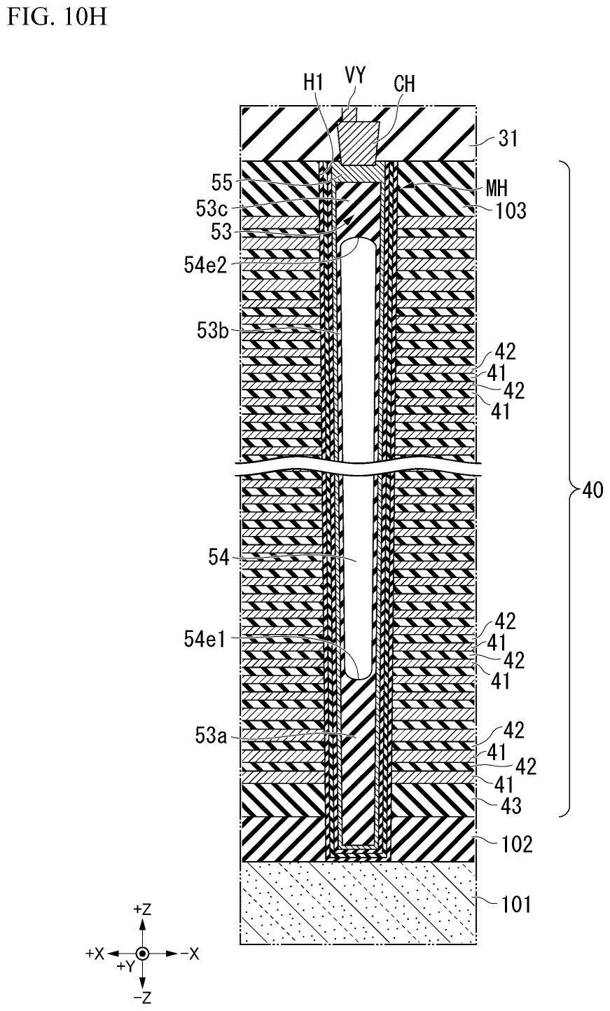

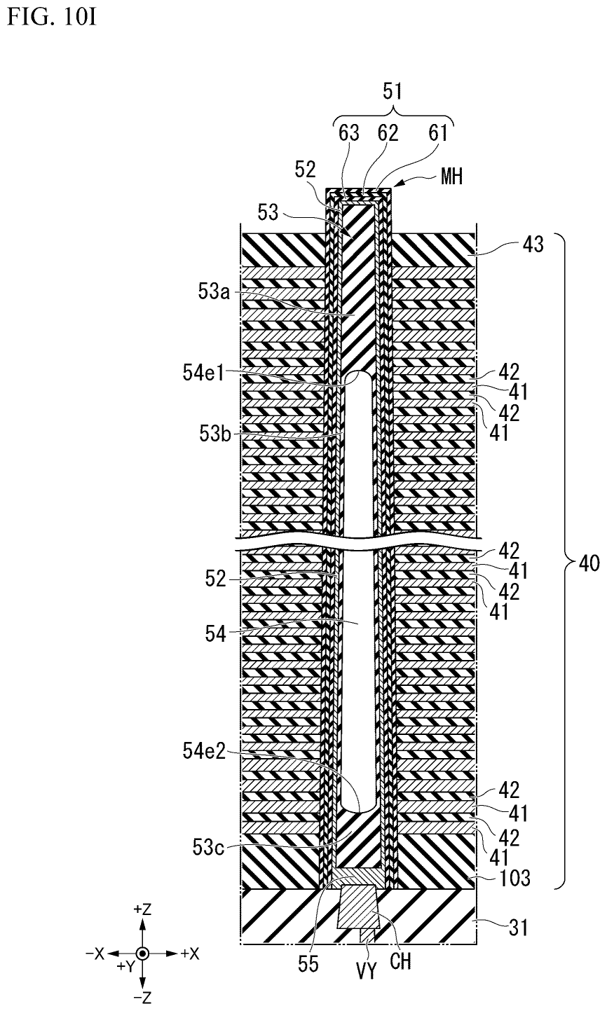

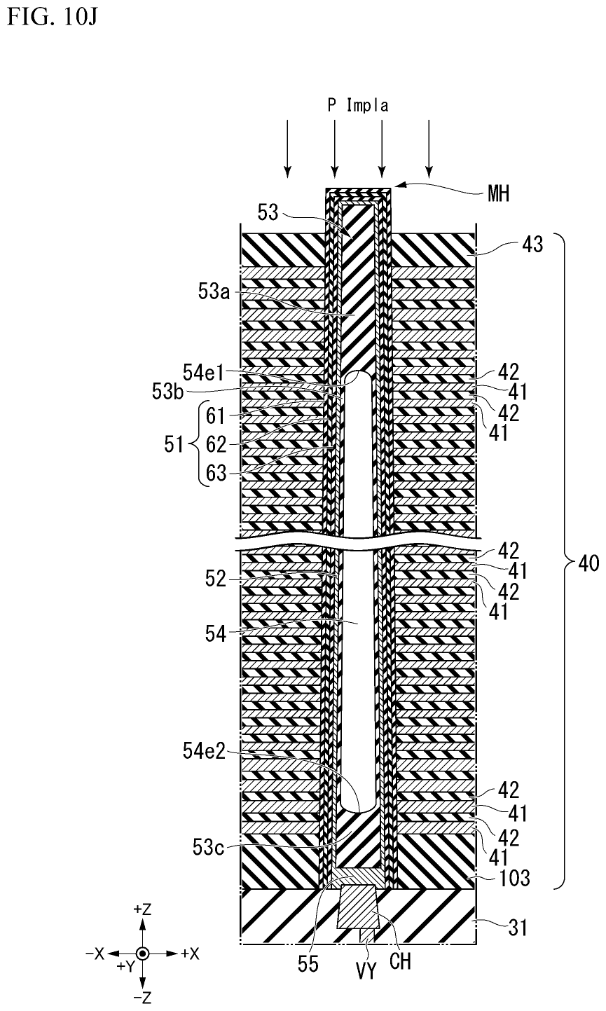

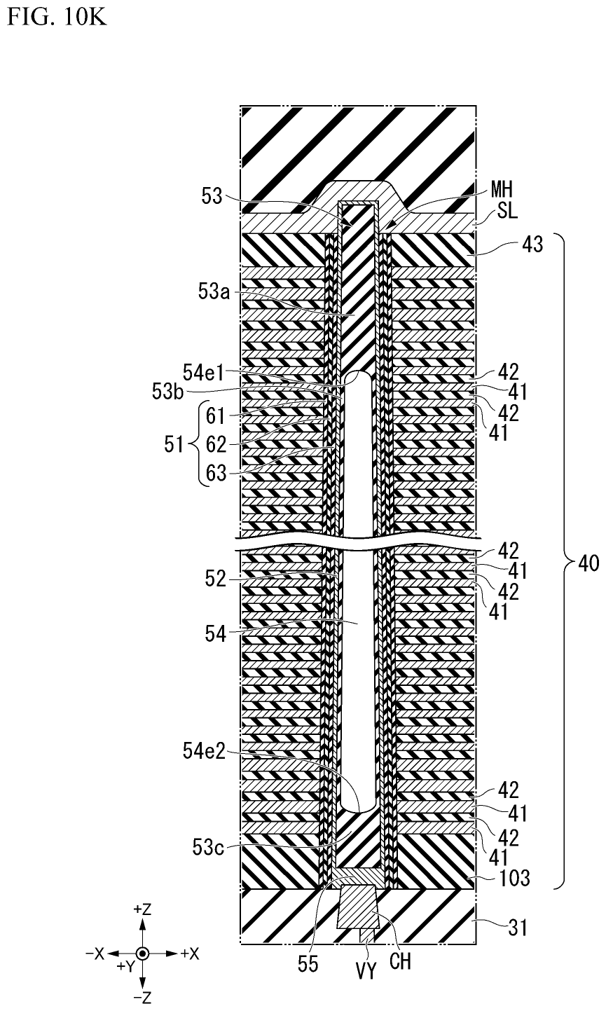

FIGS. 10A to 10K are explanatory cross-sectional views of the method of manufacturing the semiconductor storage device 1. FIGS. 10A to 10K are shown based on a posture during manufacturing.

First, as shown in FIG. 10A, an insulating layer 102 is formed on a semiconductor substrate 101. Next, the insulating layer 43 is formed on the insulating layer 102. Next, sacrificial layers 111 and the insulating layers 42 are alternately stacked one by one in the Z direction on the insulating layer 43. For example, the sacrificial layers 111 are formed of layers containing silicon and nitrogen (for example, silicon nitride films). The sacrificial layers 111 are layers to be replaced by the gate electrode layers 41 in the replacement step, which will be described below. Next, an insulating layer 103 is formed on the sacrificial layer 111 at the top. Accordingly, a multi-layered body 40A including the insulating layer 43, a plurality of sacrificial layers 111, a plurality of insulating layers 42, and the insulating layer 103 is formed. The sacrificial layers 111 are examples of each of “a first layer” and “a first insulating layer”. The insulating layers 42 are examples of each of “a second layer” and “a second insulating layer”.

Next, as shown in FIG. 10B, a hole H1 is formed in the multi-layered body 40A by etching, for example. The hole H1 penetrates the insulating layer 103, the plurality of sacrificial layers 111, the plurality of insulating layers 42, and the insulating layer 43 in the Z direction. The hole H1 is a hole in which the memory pillar MH is formed in the following step.

Next, as shown in FIG. 10C, materials of the first part 61a of the block insulating film 61, the charge trapping film 62, the tunnel insulating film 63, and the channel layer 52 are supplied to the inside of the hole H1 in order. Accordingly, the first part 61a of the block insulating film 61, the charge trapping film 62, the tunnel insulating film 63, and the channel layer 52 are formed inside the hole H1. Accordingly, a memory film 51A is formed by the first part 61a of the block insulating film 61, the charge trapping film 62, and the tunnel insulating film 63.

Next, as shown in FIG. 10D, an insulation material is supplied to the inner circumferential side of the channel layer 52. Accordingly, an insulating portion 121 is formed in a lower portion (for example, the lower end portion) of the hole H1 on the inner circumferential side of the channel layer 52. For example, the insulating portion 121 is formed of a material containing silicon and oxygen (for example, silicon oxide).

For example, the insulating portion 121 is formed by alternately performing forming an insulating film by an atomic layer deposition method (ALD) and supplying gas (for example, nitrogen trifluoride (NF3)) for suppressing formation of an insulating film on side surfaces of the channel layer 52. For example, the insulating portion 121 is formed in only the lower portion (for example, the lower end portion) of the hole H1 using the foregoing technique. The technique of forming the insulating portion 121 is not limited to the example described above. Instead of the foregoing example, a technique of forming the insulating portion 121 above the lower end portion of the hole H1 may be used.

Next, as shown in FIG. 10E, unnecessary parts of the insulating portion 121 are eliminated. Accordingly, among the plurality of sacrificial layers 111, parts of the insulating portion 121 adjacent to the sacrificial layers 111, which will be replaced by the data word lines WLA in the replacement step (which will be described below), in the X direction and the Y direction are eliminated. Accordingly, for example, in the parts adjacent to the sacrificial layers 111, which will be replaced by the data word lines WLA, in the X direction and the Y direction, the channel layer 52 is in an exposed state inside the hole H1. For example, elimination of the unnecessary parts of the insulating portion 121 can be performed by wet etching using a dilute hydrofluoric acid. By performing this step, the first insulating portion 53a described above is formed from the insulating portion 121 whose unnecessary parts are eliminated. Accordingly, it is easy to form the second insulating portion 53b in regions corresponding to many word lines WL (for example, all the data word lines WLA).

Next, as shown in FIG. 10F, an insulation material is supplied to the inner circumferential side of the channel layer 52 under supply conditions adjusted in advance. Accordingly, the second insulating portion 53b and the third insulating portion 53c are formed such that the cavity portion 54 is formed inside the memory pillar MH. That is, the second insulating portion 53b is along the inner circumferential surface of the channel layer 52 and in which the cavity portion 54 is present on the inner circumferential side, and the third insulating portion 53c which blocks the upper end portion of the second insulating portion 53b are formed. As described above, the second insulating portion 53b may be partially interrupted in the middle in the Z direction.

Next, as shown in FIG. 10G, unnecessary parts of the insulating portion 53 are eliminated, and the cap portion 55 is formed. Accordingly, the main portion of the memory pillar MH is formed.

Next, as shown in FIG. 10H, the replacement step is performed. In the replacement step, a wet etching solution is supplied from a groove (not shown), and the plurality of sacrificial layers 111 are eliminated. Next, the plurality of gate electrode layers 41 are formed by supplying a conductive material to the spaces from which the plurality of sacrificial layers 111 are eliminated. Accordingly, the multi-layered body 40 described above is formed. Thereafter, the contacts CH, the contacts VY, and the plurality of bit lines BL, the wiring portion 70, the insulating portion 31, and the like are formed. Accordingly, the chip 3 described above is formed.

Next, as shown in FIG. 10I, the chip 3 is reversed upside down, and the separately formed chip 2 and the chip 3 are adhered. Next, for example, the semiconductor substrate 101 and the insulating layer 102 are eliminated by etching. Accordingly, the upper end portion of the memory film 51 is exposed to the outside.

Next, as shown in FIG. 10J, impurities (for example, phosphorus) are implanted from the side in the +Z direction. In the present embodiment, the first insulating portion 53a which is comparatively thick in the X direction is present in the upper end portion of the memory pillar MH. For this reason, impurities are likely to be incorporated into the first insulating portion 53a, and impurities are unlikely to move toward the second insulating portion 53b. For this reason, the insulating portion 53 has a profile in which the impurity concentration in the Z direction changes significantly inside the first insulating portion 53a.

Next, as shown in FIG. 10K, unnecessary parts (upper end portion) of the memory film 51 are eliminated. Next, the source line SL is formed such that the insulating layer 43 and the upper end portion of the memory pillar MH are covered. Next, the remaining insulating portion and the like are formed. Accordingly, the semiconductor storage device 1 is completed.

### 9. Operations

Next, an example of operations of the semiconductor storage device 1 will be described.

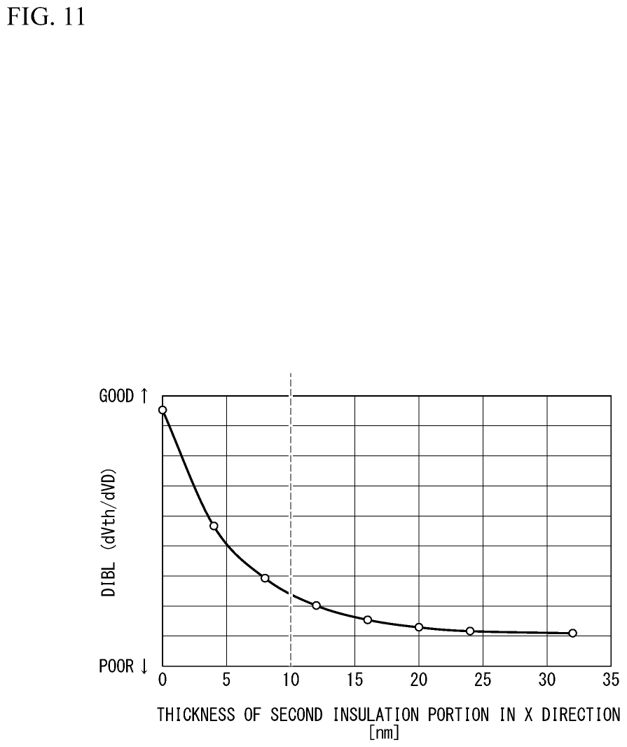

FIG. 11 is an explanatory view showing an influence of the thickness T2 of the second insulating portion 53b in the X direction. FIG. 11 shows a relationship found through research of the inventors, which is a relationship between the thickness T2 of the second insulating portion 53b in the X direction and drain-induced barrier lowering (DIBL). The aforementioned “drain-induced barrier lowering” means susceptibility to fluctuation of the threshold voltage of the memory cell transistor MT due to the drain voltage.

As shown in FIG. 11, the inventors have found that the drain-induced barrier lowering is enhanced as the thickness T2 of the second insulating portion 53b in the X direction decreases. For example, the inventors have found that improvement in drain-induced barrier lowering is quickly enhanced if the thickness T2 of the second insulating portion 53b in the X direction becomes equal to or smaller than 10 nm.

### 10. Advantages

In recent years, semiconductor storage devices are expected to have higher densities. However, as the densities of semiconductor storage devices are further increased, an influence of interference of adjacent word lines WL increases so that the distribution of threshold voltages of the memory cell transistors MT may become wider. If the distribution of the threshold voltages of the memory cell transistors MT becomes wider, electrical characteristics of semiconductor storage devices will deteriorate.

Hence, the semiconductor storage device 1 of the present embodiment includes the multi-layered body 40 and the memory pillars MH. The memory pillars MH each include the memory film 51 including the charge accumulation portion 62a, the channel layer 52 provided on the inner circumferential side of the memory film 51 in the X direction, the insulating portion 53 provided on the inner circumferential side of the channel layer 52 in the X direction, and the cavity portion 54 adjacent to at least a part of the insulating portion 53 in the Z direction. The insulating portion 53 includes the first insulating portion 53a adjacent to the plurality of source-side selection gate lines SGS in the X direction, and the second insulating portion 53b adjacent to the cavity portion 54 in the X direction and adjacent to at least a part of the word lines WL included in the plurality of word lines WL in the X direction. When the region R between the centerline CL and the channel layer 52 is viewed, the thickness T2 of the second insulating portion 53b in the X direction is smaller than the thickness T1 of the first insulating portion 53a in the X direction.

According to such a constitution, since the thickness T2 of the second insulating portion 53b in the X direction is small, the drain-induced barrier lowering is improved, and widening of the distribution of the threshold voltages of the memory cell transistors MT can be suppressed. For this reason, even when the density of the semiconductor storage device 1 is increased, increase of an influence of interference of adjacent word lines WL can be suppressed. Accordingly, improvement in electrical characteristics of the semiconductor storage device 1 can be achieved.

On the other hand, when the thickness T1 of the first insulating portion 53a in the X direction is large, change in impurity concentration in the first insulating portion 53a in the Z direction can be increased. If change in impurity concentration in the first insulating portion 53a in the Z direction can be increased, a gate-induced drain leakage (GIDL) current generated using the source-side selection gate lines SGS can be increased. If the GIDL current can be increased, it is easy to perform erasing operation of erasing data stored in the memory cell transistors MT. From this viewpoint as well, improvement in electrical characteristics of the semiconductor storage device 1 can be achieved.

In the present embodiment, when the region R is viewed, the maximum thickness T2max of the second insulating portion 53b in the X direction is smaller than the maximum thickness T1max of the first insulating portion 53a in the X direction. According to such a constitution, since the thickness T2 of the second insulating portion 53b in the X direction is smaller, it is easy to further improve the drain-induced barrier lowering.

In the present embodiment, when the region R is viewed, the maximum thickness T2max of the second insulating portion 53b in the X direction is smaller than the minimum thickness T1min of the first insulating portion 53a in the X direction. According to such a constitution, since the thickness T2 of the second insulating portion 53b in the X direction is smaller, it is easy to further improve the drain-induced barrier lowering.

In the present embodiment, when the region R is viewed, the thickness T2 of the second insulating portion 53b in the X direction is equal to or smaller than half the thickness T1 of the first insulating portion 53a in the X direction. According to such a constitution, since the thickness T2 of the second insulating portion 53b in the X direction is smaller, it is easy to further improve the drain-induced barrier lowering.

In the present embodiment, the second insulating portion 53b is adjacent to the plurality of data word lines WLA in the X direction. When the region R is viewed, the thickness T2 of the second insulating portion 53b in the X direction is smaller than the thickness T1 of the first insulating portion 53a in the X direction over the entire length of the second insulating portion 53b in the Z direction. According to such a constitution, it is easy to further improve the drain-induced barrier lowering for the memory cell transistors MT corresponding to the plurality of data word lines WLA.

In the present embodiment, the minimum thickness T2min of the second insulating portion 53b in the X direction is equal to or smaller than 10 nm. According to such a constitution, since the thickness T2 of the second insulating portion 53b in the X direction is smaller, it is easy to further improve the drain-induced barrier lowering.

In the present embodiment, the concentration of impurities included in the first insulating portion 53a is higher than the concentration of impurities included in the second insulating portion 53b. According to such a constitution, change in concentration of impurities in the first insulating portion 53a in the Z direction can be further increased. Accordingly, it is easy to increase the GIDL current generated using the source-side selection gate lines SGS.

In the present embodiment, the degree of change in impurity concentration in the first insulating portion 53a in the Z direction is higher than the degree of change in impurity concentration in the second insulating portion 53b in the Z direction. According to such a constitution, change in concentration of impurities in the first insulating portion 53a in the Z direction can be further increased. Accordingly, it is easy to increase the GIDL current generated using the source-side selection gate lines SGS.

In the present embodiment, the first end 54e1 of the cavity portion 54 is positioned on the side in the −Z direction from the plurality of source-side selection gate lines SGS. According to such a constitution, it is easy to increase the thickness of the first insulating portion 53a in the X direction. Accordingly, it is easy to further increase change in impurity concentration in the first insulating portion 53a in the Z direction so that it is easy to increase the GIDL current generated using the source-side selection gate lines SGS.

In the present embodiment, the first end 54e1 of the cavity portion 54 is positioned on the side in the −Z direction from one word line WL (for example, one dummy word line WLD1) closest to the plurality of source-side selection gate lines SGS among the plurality of word lines WL. According to such a constitution, it is easy to form the first insulating portion 53a adjacent to the plurality of source-side selection gate lines SGS to have a large thickness in the X direction. Accordingly, it is easy to further increase change in impurity concentration in the first insulating portion 53a in the Z direction so that it is easy to further increase the GIDL current generated using the source-side selection gate lines SGS.

### 11. Modification Examples

Next, several modification examples will be described. In each of the modification examples, constituents other than those described below are the same as the constituents of the first embodiment described above.

### First Modification Example

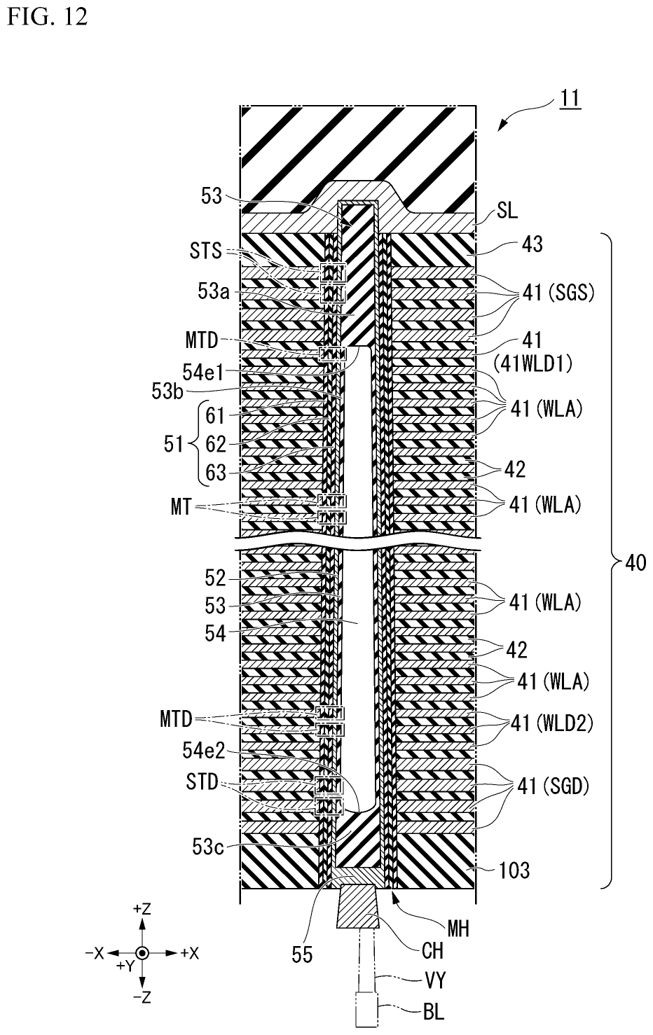

FIG. 12 is a cross-sectional view showing the memory cell array 11 of a first modification example. In the first modification example, the position of the first end 54e1 of the cavity portion 54 in the Z direction is a position between the source-side selection gate line SGS at the bottom and the first dummy word line WLD1 at the top. Even with such a constitution, it is possible to exhibit effects similar to those of the semiconductor storage device 1 of the first embodiment.

### Second Modification Example

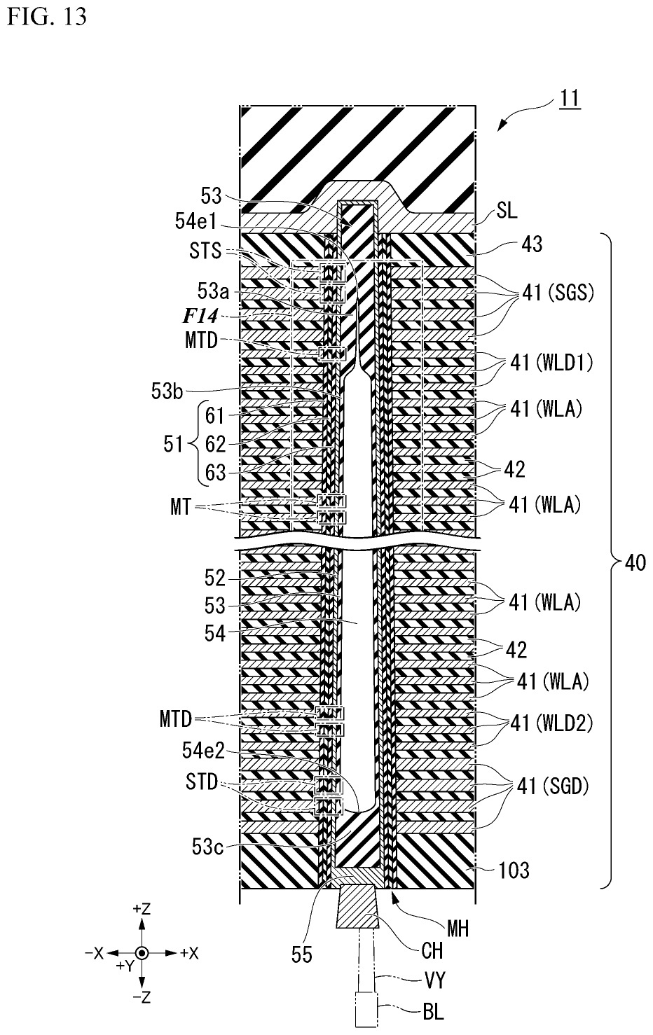

FIG. 13 is a cross-sectional view showing the memory cell array 11 of a second modification example. In the second modification example, a part of the cavity portion 54 is provided inside the first insulating portion 53a.

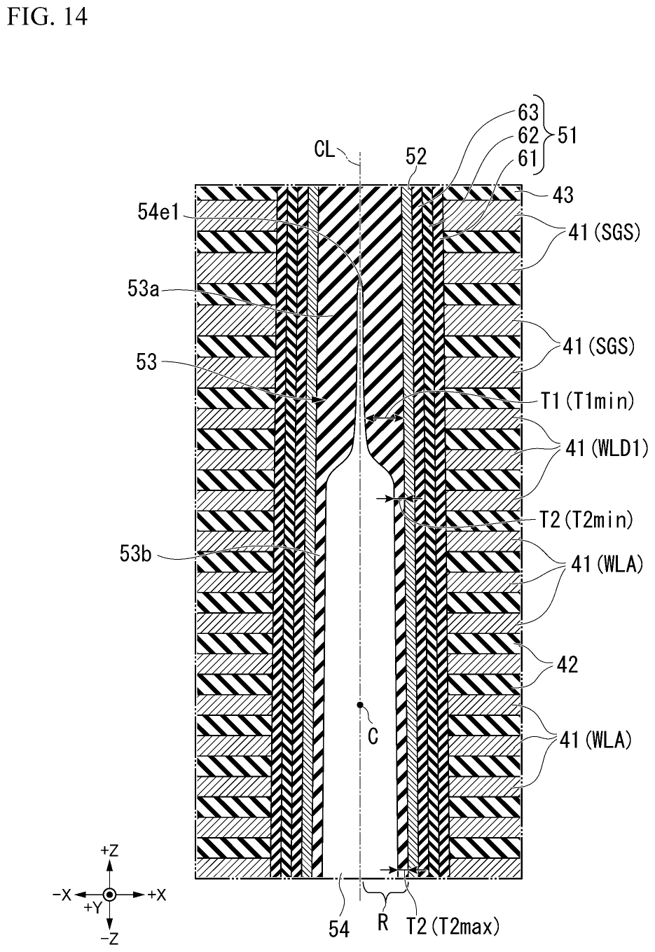

FIG. 14 is an enlarged cross-sectional view showing a region surrounded by line F14 in the memory cell array 11 shown in FIG. 13. In the present modification example, the minimum thickness T1min of the first insulating portion 53a in the X direction is a dimension between the cavity portion 54 and the channel layer 52. Even with such a constitution, it is possible to exhibit effects similar to those of the semiconductor storage device 1 of the first embodiment.

### Second Embodiment

Next, a second embodiment will be described. The second embodiment differs from the first embodiment in that the second insulating portion 53b is not present. Constituents other than those described below are the same as the constituents of the first embodiment.

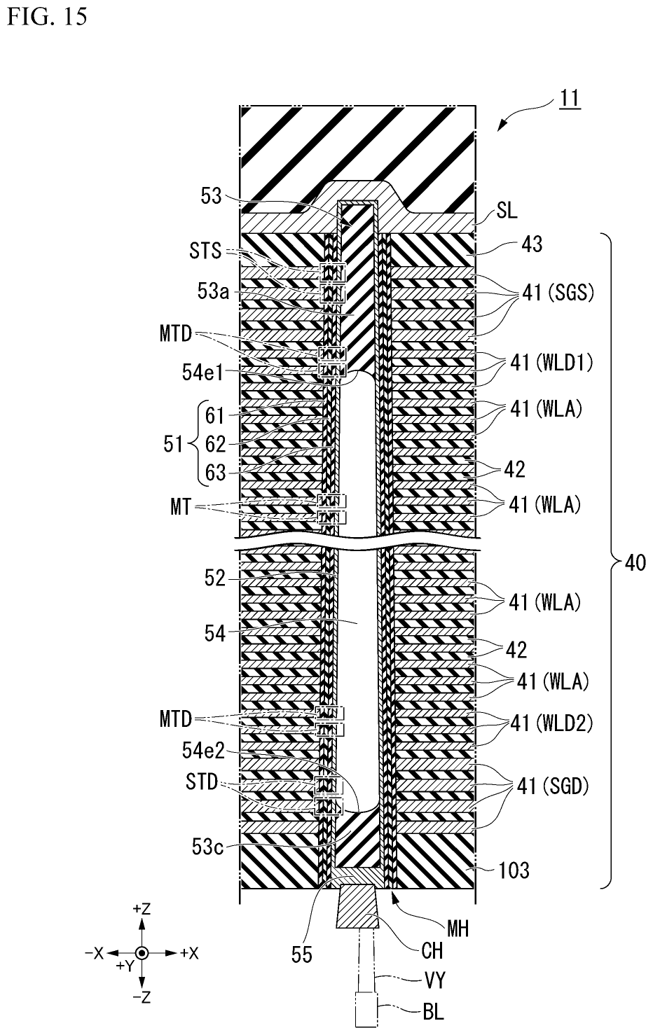

FIG. 15 is a cross-sectional view showing the memory cell array 11 of the second embodiment. In the present embodiment, the insulating portion 53 does not have the second insulating portion 53b. The insulating portion 53 is formed by the first insulating portion 53a and the third insulating portion 53c. In the present embodiment, the inner surface of the channel layer 52 is exposed to the cavity portion 54 in a region adjacent to the plurality of data word lines WLA. Even with such a constitution, it is possible to exhibit effects similar to those of the semiconductor storage device 1 of the first embodiment.

### Third Embodiment

Next, a third embodiment will be described. The third embodiment differs from the first embodiment in that division portions SHEU dividing the source-side selection gate lines SGS are provided. Constituents other than those described below are the same as the constituents of the first embodiment.

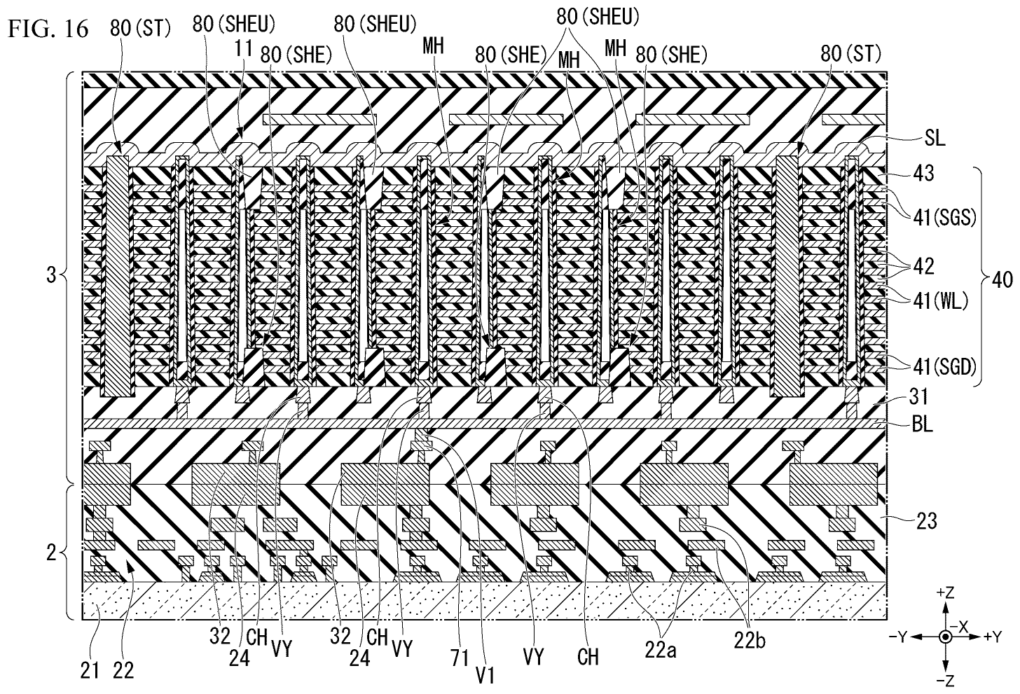

FIG. 16 is a cross-sectional view showing the memory cell array 11 of the third embodiment. In the present embodiment, the plurality of division portions 80 have the plurality of division portions SHEU in addition to the division portions ST and the division portions SHE described above. The division portions SHEU are division portions having shorter lengths in the Z direction than the division portions ST and are wall portions dividing the upper end portion of the multi-layered body 40 in the Y direction. The plurality of division portions SHEU are disposed in a manner of being divided in the Y direction. In the present embodiment, a plurality of (for example, four) division portions SHEU are present between two division portions ST adjacent to each other in the Y direction. The division portions SHEU are provided in the upper end portion of the multi-layered body 40. The division portions SHEU extend in the Z direction halfway through the multi-layered body 40. The division portions SHEU extend in the X direction. That is, the division portions SHEU are wall portions lying in the Z direction and the X direction.

The division portions SHEU penetrate a part of the gate electrode layers 41 including the uppermost layer of the plurality of gate electrode layers 41 and divide the part of the gate electrode layers 41 in the Y direction. For example, the division portions SHEU penetrate each of all the gate electrode layers 41 functioning as the source-side selection gate lines SGS. The division portions SHEU may penetrate each of a part or all of the gate electrode layers 41 functioning as the first dummy word lines WLD1. On the other hand, the division portions SHEU do not reach the gate electrode layers 41 functioning as the data word lines WLA. The division portions SHEU divide only the gate electrode layers 41 functioning as the source-side selection gate lines SGS in the Y direction. For example, the division portions SHEU are formed of a film containing silicon and oxygen (for example, a silicon oxide film).

Even with such a constitution, it is possible to exhibit effects similar to those of the semiconductor storage device 1 of the first embodiment.

Hereinabove, a plurality of embodiments and modification examples have been described. However, the embodiments and the modification examples are not limited to the examples described above. For example, the embodiments and the modification examples described above may be realized by being combined together.

According to at least one of the embodiments described above, a semiconductor storage device includes a multi-layered body, a columnar body, and a bit line. The multi-layered body includes a plurality of gate electrode layers and a plurality of insulating layers. When a direction intersecting the first direction is a second direction and a virtual centerline extending in the first direction through a center of the columnar body in the second direction is defined, it is as follows. The columnar body includes a memory film, a semiconductor film, and an insulating portion. The insulating portion includes a first insulating portion adjacent to the plurality of first selection gate lines, and a second insulating portion adjacent to at least a part of word lines. When a region between the centerline and the semiconductor film is viewed, a thickness of the second insulating portion in the second direction is smaller than a thickness of the first insulating portion in the second direction. According to such a constitution, improvement in electrical characteristics of the semiconductor storage device can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a multi-layered body including a plurality of gate electrode layers and a plurality of insulating layers, the plurality of gate electrode layers and the plurality of insulating layers being alternately stacked one by one in a first direction;
a columnar body extending in the first direction inside the multi-layered body; and
a bit line on a first side in the first direction with respect to the columnar body, wherein
the plurality of gate electrode layers include
a plurality of word lines forming first intersecting portions with the columnar body, the first intersecting portions having memory cell transistors, and
a plurality of first selection gate lines on a second side opposite to the first side with respect to the plurality of word lines, the plurality of first selection gate lines forming second intersecting portions with the columnar body, the second intersecting portions having first selection transistors,
when a direction intersecting the first direction is a second direction, the columnar body includes
a memory film including a charge accumulation portion,
a semiconductor film on an inner circumferential side of the memory film in the second direction,
an insulating portion on an inner circumferential side of the semiconductor film in the second direction, and
a cavity portion adjacent to at least a part of the insulating portion in the first direction,
the insulating portion includes
a first insulating portion adjacent to the plurality of first selection gate lines in the second direction, and
a second insulating portion adjacent to the cavity portion in the second direction, the second insulating portion being adjacent to at least a part of word lines included in the plurality of word lines in the second direction, and
when a virtual centerline extending in the first direction through a center of the columnar body in the second direction is defined in a cross section in the first direction and the second direction, and when a region between the centerline and the semiconductor film is viewed, a thickness of the second insulating portion in the second direction is smaller than a thickness of the first insulating portion in the second direction.

2. The semiconductor storage device according to claim 1, wherein
when the region is viewed, a maximum thickness of the second insulating portion in the second direction is smaller than a maximum thickness of the first insulating portion in the second direction.

3. The semiconductor storage device according to claim 1, wherein
when the region is viewed, a maximum thickness of the second insulating portion in the second direction is smaller than a minimum thickness of the first insulating portion in the second direction.

4. The semiconductor storage device according to claim 1, wherein
when the region is viewed, the thickness of the second insulating portion in the second direction is equal to or smaller than half the thickness of the first insulating portion in the second direction.

5. The semiconductor storage device according to claim 1, wherein
the plurality of gate electrode layers further include a plurality of second selection gate lines,
the plurality of second selection gate lines are disposed on the first side with respect to the plurality of word lines,
the plurality of second selection gate lines forms third intersecting portions with the columnar body,
the third intersecting portions has second selection transistors,
the plurality of word lines include five or fewer first word lines, five or fewer second word lines, and a plurality of third word lines,
the first word lines are closest to the plurality of first selection gate lines in the plurality of word lines,
the second word lines are closest to the plurality of second selection gate lines in the plurality of word lines,
the third word lines are remaining word lines among the plurality of word lines other than the first word lines and the second word lines,
the second insulating portion is adjacent to the plurality of third word lines in the second direction, and
when the region is viewed, the thickness of the second insulating portion in the second direction is smaller than the thickness of the first insulating portion in the second direction throughout an entire length of the second insulating portion in the first direction.

6. The semiconductor storage device according to claim 1, wherein
the memory film includes a first insulating film, a charge trapping film, and a second insulating film,
the charge trapping film is on an inner circumferential side of the first insulating film,
the second insulating film is on an inner circumferential side of the charge trapping film,
the thickness of the second insulating portion in the second direction is smaller than a thickness of the memory film in the second direction.

7. The semiconductor storage device according to claim 1, wherein
a minimum thickness of the second insulating portion in the second direction is equal to or smaller than 10 nm.

8. The semiconductor storage device according to claim 1, wherein
when viewed in a direction traveling toward the first side in the first direction, a rate of decrease in impurity concentration in the first insulating portion is higher than a rate of decrease in impurity concentration in the second insulating portion.

9. The semiconductor storage device according to claim 1, wherein
the cavity portion has an end on the second side,
the end of the cavity portion is closer to the first side than the plurality of first selection gate lines.

10. The semiconductor storage device according to claim 1, wherein
the cavity portion has an end on the second side,
the end of the cavity portion is closer to the first side than one word line closest to the plurality of first selection gate lines in the plurality of word lines.

11. The semiconductor storage device according to claim 1, wherein
the semiconductor film is exposed to the cavity portion at a position adjacent to a part of the word lines included in the plurality of word lines in the second direction.

12. A semiconductor storage device comprising:
a multi-layered body including a plurality of gate electrode layers and a plurality of insulating layers, the plurality of gate electrode layers and the plurality of insulating layers being alternately stacked one by one in a first direction;
a columnar body extending in the first direction inside the multi-layered body; and
a bit line on a first side in the first direction with respect to the columnar body, wherein
the plurality of gate electrode layers include
a plurality of word lines forming first intersecting portions with the columnar body, the first intersecting portions having memory cell transistors, and
a plurality of first selection gate lines on a second side opposite to the first side with respect to the plurality of word lines, the plurality of first selection gate lines forming second intersecting portions with the columnar body, the second intersecting portions having first selection transistors,
when a direction intersecting the first direction is a second direction, the columnar body includes
a memory film including a charge accumulation portion,
a semiconductor film on an inner circumferential side of the memory film in the second direction,
an insulating portion on an inner circumferential side of the semiconductor film in the second direction, and
a cavity portion adjacent to at least a part of the insulating portion in the first direction,
the insulating portion includes a part adjacent to the plurality of first selection gate lines in the second direction, and
the semiconductor film is exposed to the cavity portion at a position adjacent to at least a part of the word lines included in the plurality of word lines in the second direction.

13. A method of manufacturing a semiconductor storage device comprising:
forming a multi-layered body including first layers and second layers, the first layers and the second layers being alternately stacked in a first direction;
forming a hole extending in the first direction in the multi-layered body;
forming a memory film and a semiconductor film along an inner circumferential surface of the hole, the memory film including a charge accumulation portion, the semiconductor film being on an inner circumferential side of the memory film;
forming an insulating portion in a lower portion of the hole on an inner circumferential side of the semiconductor film;
forming a first insulating portion by eliminating an upper end portion of the insulating portion through wet etching; and
forming a second insulating portion and a third insulating portion, the second insulating portion being along an inner circumferential surface of the semiconductor film, the second insulating portion having an inner circumferential side and an upper end portion, the inner circumferential side of the second insulating portion having a cavity portion, the third insulating portion blocking the upper end portion of the second insulating portion.
